(19) United States
(12) Patent Application Publication
(10) Pub. No.: US 2026/0341362 A1
(43) Pub. Date: Oct. 29, 2026

(54) MULTI-PASS PROGRAMMING TECHNIQUES FOR MEMORY DEVICES

(71) Applicant: Sandisk Technologies, Inc., Milpitas, CA (US)

(72) Inventors: Kaoru Masada, Fujisawa (JP); Rikuo Yugeta, Fujisawa (JP); Zhaoxing Qin, Kanagawa (JP); Norihiro Kamae, Yokohama (JP); Noritoshi Shinto, Fujisawa (JP); Tatsuya Yamada, Kamakura (JP); Kazuki Yamauchi, Misato (JP); Ken Oowada, Fujisawa (JP)

(21) Appl. No.: 19/193,243

(22) Filed: Apr. 29, 2025

(51) Int. Cl. G11C 16/10

(52) U.S. Cl. CPC G11C 16/10

(57) ABSTRACT

The multi-pass programming techniques improve both reliability and performance. The memory cells of a selected word line are programmed in a first pass to include “foggy data” that is not readable on its own. Two bits of parity data are programmed into a separate location in the memory device (for example, a parity block) to assist with decoding the foggy data. Prior to a second pass, the foggy data is read in a read operation that includes reading the data states one at a time in a series of read operations and performing a decoding operation on each data state prior to advancing to reading a next one of the data states.

### BACKGROUND

### 1. Field

The subject disclosure is related generally to memory devices and, more particularly, to improved programming techniques to enhance performance and minimize host resource usage.

### 2. Related Art

Semiconductor memory is widely used in various electronic devices, such as cellular telephones, digital cameras, personal digital assistants, medical electronics, mobile computing devices, servers, solid state drives, non-mobile computing devices and other devices. Semiconductor memory may comprise non-volatile memory or volatile memory. A non-volatile memory allows information to be stored and retained even when the non-volatile memory is not connected to a source of power, e.g., a battery.

NAND memory devices include a chip with a plurality of memory blocks, each of which includes an array of memory cells arranged in a plurality of word lines. The memory cells can be programmed to have threshold voltages that are associated with data states in a programming operation. In some cases, the memory cells are programmed directly to the threshold voltages associated with their intended programmed data states in a full-sequence programming operation. In some other cases, the memory cells are programmed to their final threshold voltages in two or more programming passes, each of which includes a plurality of program loops.

### SUMMARY

One aspect of the present disclosure is related to a method of programming a memory device. The method includes the step of preparing a selected memory block which includes an array of memory cells that are arranged in a plurality of word lines. The method proceeds with the step of receiving instructions to program multiple pages of user data into a selected word line of the plurality of word lines. In a first programming pass, the method continues with the step of programming the memory cells of the selected word line to a plurality of data states such that the selected word line contains foggy data. The method proceeds with the step of programming parity data to a parity memory block. The method continues with the step of reading the parity data. The method proceeds with the steps of reading the foggy data one data state at a time in a series of read operations and performing a decoding operation using the parity data during the reading of each data state prior to proceeding to read a next data state until all of the plurality of data states have been read and the user data has been decoded. The method continues with the step of further programming the memory cells in a second programming pass from the foggy data to the user data.

According to another aspect of the present disclosure, the foggy data is read one data state at a time starting with a data state that is associated with a highest threshold voltage range and ending with a data state that is associated with a lowest threshold voltage range.

According to yet another aspect of the present disclosure, the user data includes four pages of data.

According to still another aspect of the present disclosure, the parity data includes two pages of data.

According to a further aspect of the present disclosure, the plurality of data states includes at least fifteen programmed data states.

According to yet a further aspect of the present disclosure, the step of reading the parity data includes storing the parity data into data latches, and a sensing capacitor is used as a virtual data latch.

According to still a further aspect of the present disclosure, the first programming pass includes a plurality of program loops with programming pulses, and a programming voltage increases by a first step size between program loops. The second programming pass includes a plurality of program loops with programming pulses, and the programming voltage increase by a second step size between program loops. The second step size is less than the first step size.

Another aspect of the present disclosure is related to a memory device that includes a selected memory block with an array of memory cells that are arranged in a plurality of word lines. The memory device also includes circuitry for programming the memory cells of a selected word line of the plurality of word lines. The circuitry is configured to receive instructions to program multiple pages of user data into the selected word line. In a first programming pass, the circuitry is configured to program the memory cells of the selected word line to a plurality of data states such that the selected word line contains foggy data. The circuitry is further configured to program parity data into a parity memory block and then later read the parity data. The circuitry is then configured to read the foggy data one data state at a time in a series of read operations and perform a decoding operation using the parity data during the reading of each data state prior to proceeding to read a next data state until all of the plurality of data states have been read and the user data has been decoded. The circuitry is also configured to further program the memory cells in a second programming pass from the foggy data to the user data.

According to another aspect of the present disclosure, the circuitry is configured to read the foggy data one data state at a time starting with a data state that is associated with a highest threshold voltage range and ending with a data state that is associated with a lowest threshold voltage range.

According to yet another aspect of the present disclosure, the user data includes four pages of data.

According to still another aspect of the present disclosure, the parity data includes two pages of data.

According to a further aspect of the present disclosure, the plurality of data states includes at least fifteen programmed data states.

According to yet a further aspect of the present disclosure, when reading the parity data, the circuitry is configured to store the parity data into data latches.

According to still a further aspect of the present disclosure, the first programming pass includes a plurality of program loops with programming pulses, and a programming voltage increases by a first step size between program loops. The second programming pass includes a plurality of program loops with programming pulses, and the programming voltage increases by a second step size between program loops. The second step size is less than the first step size.

Yet another aspect of the present disclosure is related to an apparatus that includes a selected memory block with an array of memory cells that are arranged in a plurality of word lines and and with at least one parity memory block. The apparatus also includes a programming means for programming the memory cells of a selected word line of the plurality of word lines. The programming means is configured to receive instructions to program multiple pages of user data into the selected word line. In a first programming pass, the programming means is configured to program the memory cells of the selected word line to at least fifteen programmed data states such that the selected word line contains foggy data. The at least fifteen data states include a first data state that is associated with a first threshold voltage range and a last data state that is associated with a second threshold voltage range that is greater than the first threshold voltage range. The programming means is also configured to program at least two pages of parity data into the parity memory block and then later read the parity data. The programming means is further configured to read the foggy data one data state at a time in a series of read operations starting with the last data state and ending at the first data state and perform a decoding operation using the parity data during the reading of each data state prior to proceeding to read a next data state until all of the at least fifteen data states have been read and the user data has been decoded. The programming means is also configured to further program the memory cells in a second programming pass from the foggy data to the user data.

According to another aspect of the present disclosure, the foggy data includes threshold voltage distribution curves for each of the at least fifteen data states, and at least three threshold voltage distribution curves overlap for some threshold voltage ranges.

According to yet another aspect of the present disclosure, the user data includes four pages of data.

According to still another aspect of the present disclosure, the parity data includes two pages of data.

According to a further aspect of the present disclosure, the parity data is programmed in a single bit per memory cell storage format.

According to yet a further aspect of the present disclosure, the first programming pass includes a plurality of program loops with programming pulses, and a programming voltage increases by a first step size between program loops. The second programming pass includes a plurality of program loops with programming pulses, and the programming voltage increases by a second step size between program loops. The second step size is less than the first step size.

### BRIEF DESCRIPTION OF THE DRAWINGS

A more detailed description is set forth below with reference to example embodiments depicted in the appended figures. Understanding that these figures depict only example embodiments of the disclosure and are, therefore, not to be considered limiting of its scope. The disclosure is described and explained with added specificity and detail through the use of the accompanying drawings in which:

FIG. 1A is a block diagram of an example memory device;

FIG. 1B is a block diagram of an example control circuit;

FIG. 2 depicts blocks of memory cells in an example two-dimensional configuration of the memory array of FIG. 1A;

FIG. 3A and FIG. 3B depict cross-sectional views of example floating gate memory cells in NAND strings;

FIG. 4A and FIG. 4B depict cross-sectional views of example charge-trapping memory cells in NAND strings;

FIG. 5 depicts an example block diagram of the sense block SB1 of FIG. 1;

FIG. 6A is a perspective view of a set of blocks in an example three-dimensional configuration of the memory array of FIG. 1;

FIG. 6B depicts an example cross-sectional view of a portion of one of the blocks of FIG. 6A;

FIG. 6C depicts a plot of memory hole diameter in the stack of FIG. 6B;

FIG. 6D depicts a close-up view of region 622 of the stack of FIG. 6B;

FIG. 7A depicts a top view of an example word line layer WL0 of the stack of FIG. 6B;

FIG. 7B depicts a top view of an example top dielectric layer DL116 of the stack of FIG. 6B;

FIG. 8 depicts a threshold voltage Vt distribution plot of a plurality of memory cells programmed according to a one bit per memory cell (SLC) storage scheme;

FIG. 9 depicts a threshold voltage Vt distribution plot of a plurality of memory cells programmed according to a two bits per memory cell (MLC) storage scheme;

FIG. 10 depicts a threshold voltage Vt distribution plot of a plurality of memory cells programmed according to a four bits per memory cell (QLC) storage scheme;

FIG. 11 is a voltage waveform of a selected word line during an example programming operation;

FIG. 12 is a threshold voltage Vt distribution plot depicting one type of multi-pass programming operation;

FIG. 13 is a threshold voltage Vt distribution plot depicting another type of multi-pass programming operation;

FIG. 14 is a threshold voltage Vt distribution plot depicting a plurality of memory cells programmed in a foggy pass according to an exemplary embodiment of the present disclosure;

FIG. 15 is a schematic view of an exemplary NAND string during a sensing operation;

FIG. 16 is a table illustrating sensing results during a foggy read and parity bits that are used to decode failed bits in the sensing results to arrive at correct results;

FIG. 17 is a flow chart depicting the steps of performing a multi-pass programming operation according to an exemplary embodiment of the present disclosure;

FIG. 18 is a waveform of the voltage applied to a selected word line during a series of read operations according to an exemplary embodiment of the present disclosure;

FIG. 19A is a table illustrating the bits stored in a plurality of data latches prior to the start of a series of read operations to read and decode the foggy data;

FIG. 19B is a table illustrating the bits stored in a plurality of data latches after a first read operation of a series of read operations to read and decode the foggy data;

FIG. 19C is a table illustrating the bits stored in a plurality of data latches after a second read operation of a series of read operations to read and decode the foggy data;

FIG. 19D is a table illustrating the bits stored in a plurality of data latches after a last read operation of a series of read operations to read and decode the foggy data;

FIG. 20A is a table of the bits stored in a plurality of data latches following a foggy read operation and prior to state correction; and

FIG. 20B is a table of the bits stored in a plurality of data latches following a foggy read operation and after a state correction.

### DESCRIPTION OF THE ENABLING EMBODIMENTS

The present disclosure is related generally to multi-pass programming techniques that improve both reliability and performance. According to these techniques, the memory cells of a selected word line are programmed in a first pass to include “foggy data”, i.e., data that is not readable on its own because the threshold voltage Vt curves of the data states overlap with one another to a greater extent than an error correction code engine is capable of correcting. Two bits of parity data are programmed into a separate location in the memory device (for example, a parity block) to assist with decoding the foggy data. Prior to a second pass, the foggy data is read in a read operation that includes reading the data states one at a time in a series of read operations and performing a decoding operation on each data state prior to advancing to reading a next one of the data states. This technique can be performed both quickly and efficiently in the memory device, thereby reducing off-chip resource usage as compared to other known multi-pass programming operations.

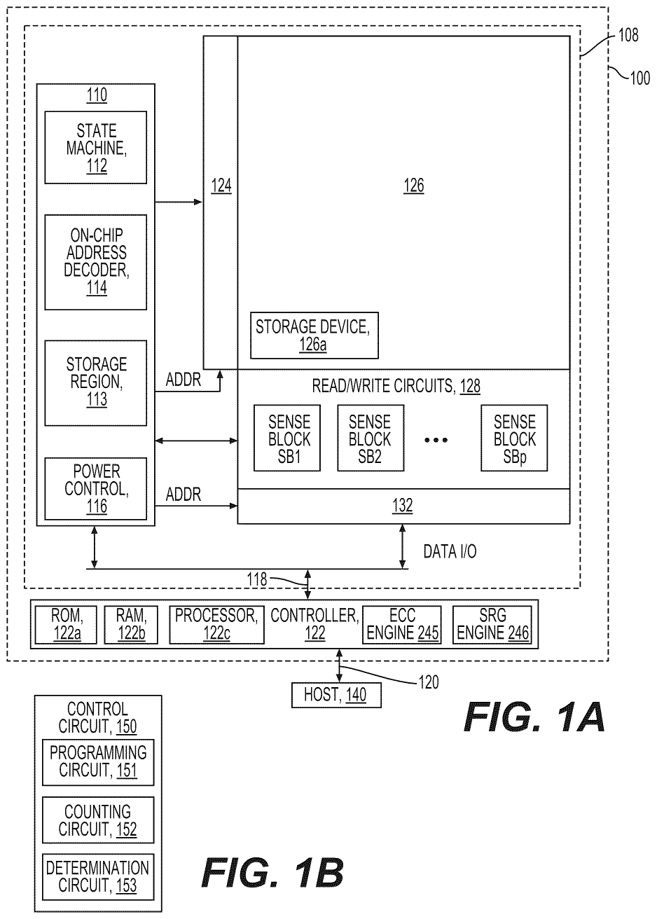

FIG. 1A is a block diagram of an example memory device 100 is configured to program the memory cells of a memory block according to the programming techniques of the subject disclosure. The memory die 108 includes a memory structure 126 of memory cells, such as an array of memory cells, control circuitry 110, and read/write circuits 128. The memory structure 126 can be addressed by word lines via a row decoder 124 and by bit lines via a column decoder 132. The read/write circuits 128 include multiple sense blocks SB1, SB2,. SBp (sensing circuitry) and allow a page of memory cells to be read or programmed in parallel. Typically, a controller 122 is included in the same memory device 100 (e.g., a removable storage card) as the one or more memory die 108. Commands and data are transferred between the host 140 and controller 122 via a data bus 120, and between the controller and the one or more memory die 108 via lines 118.

The memory structure 126 can be two-dimensional or three-dimensional. The memory structure 126 may comprise one or more arrays of memory cells, including a three-dimensional array. The memory structure 126 may comprise a monolithic three-dimensional memory structure in which multiple memory levels are formed above (and not in) a single substrate, such as a wafer, with no intervening substrates. The memory structure 126 may comprise any type of non-volatile memory that is monolithically formed in one or more physical levels of arrays of memory cells having an active area disposed above a silicon substrate. The memory structure 126 may be in a non-volatile memory device having circuitry associated with the operation of the memory cells, whether the associated circuitry is above or within the substrate.

The control circuitry 110 cooperates with the read/write circuits 128 to perform memory operations on the memory structure 126, and includes a state machine 112, an on-chip address decoder 114, and a power control module 116. The state machine 112 provides chip-level control of memory operations.

A storage region 113 may, for example, be provided for programming parameters. The programming parameters may include a program voltage, a program voltage bias, position parameters indicating positions of memory cells, contact line connector thickness parameters, a verify voltage, and/or the like. The position parameters may indicate a position of a memory cell within the entire array of NAND strings, a position of a memory cell as being within a particular NAND string group, a position of a memory cell on a particular plane, and/or the like. The contact line connector thickness parameters may indicate a thickness of a contact line connector, a substrate or material that the contact line connector is comprised of, and/or the like.

The on-chip address decoder 114 provides an address interface between that used by the host or a memory controller to the hardware address used by the decoders 124 and 132. The power control module 116 controls the power and voltages supplied to the word lines and bit lines during memory operations. It can include drivers for word lines, SGS and SGD transistors, and source lines. The sense blocks can include bit line drivers, in one approach. An SGS transistor is a select gate transistor at a source end of a NAND string, and an SGD transistor is a select gate transistor at a drain end of a NAND string.

In some embodiments, some of the components can be combined. In various designs, one or more of the components (alone or in combination), other than memory structure 126, can be thought of as at least one control circuit which is configured to perform the actions described herein. For example, a control circuit may include any one of, or a combination of, control circuitry 110, state machine 112, decoders 114/132, power control module 116, sense blocks SBb, SB2, . . . , SBp, read/write circuits 128, controller 122, and so forth.

The control circuits 150 can include a programming circuit 151 configured to perform a program and verify operation for one set of memory cells, wherein the one set of memory cells comprises memory cells assigned to represent one data state among a plurality of data states and memory cells assigned to represent another data state among the plurality of data states; the program and verify operation comprising a plurality of program and verify iterations; and in each program and verify iteration, the programming circuit performs programming for the one selected word line after which the programming circuit applies a verification signal to the selected word line. The control circuits 150 can also include a counting circuit 152 configured to obtain a count of memory cells which pass a verify test for the one data state. The control circuits 150 can also include a determination circuit 153 configured to determine, based on an amount by which the count exceeds a threshold, if a programming operation is completed.

For example, FIG. 1B is a block diagram of an example control circuit 150 which comprises the programming circuit 151, the counting circuit 152, and the determination circuit 153.

The off-chip controller 122 may comprise a processor 122c, storage devices (memory) such as ROM 122a and RAM 122b, an error-correction code (ECC) engine 245, and a data decoding engine 246. The ECC engine can correct a number of read errors that are caused when the upper tail of a Vt distribution becomes too high. However, uncorrectable errors may exist in some cases. The techniques provided herein reduce the likelihood of uncorrectable errors.

The storage device(s) 122a, 122b comprise, code such as a set of instructions, and the processor 122c is operable to execute the set of instructions to provide the functionality described herein. Alternately or additionally, the processor 122c can access code from a storage device 126a of the memory structure 126, such as a reserved area of memory cells in one or more word lines. For example, code can be used by the controller 122 to access the memory structure 126 such as for programming, read and erase operations. The code can include boot code and control code (e.g., set of instructions). The boot code is software that initializes the controller 122 during a booting or startup process and enables the controller 122 to access the memory structure 126. The code can be used by the controller 122 to control one or more memory structures 126. Upon being powered up, the processor 122c fetches the boot code from the ROM 122a or storage device 126a for execution, and the boot code initializes the system components and loads the control code into the RAM 122b. Once the control code is loaded into the RAM 122b, it is executed by the processor 122c. The control code includes drivers to perform basic tasks such as controlling and allocating memory, prioritizing the processing of instructions, and controlling input and output ports.

Generally, the control code can include instructions to perform the functions described herein including the steps of the flowcharts discussed further below and provide the voltage waveforms including those discussed further below.

In one embodiment, the host is a computing device (e.g., laptop, desktop, smartphone, tablet, digital camera) that includes one or more processors, one or more processor readable storage devices (RAM, ROM, flash memory, hard disk drive, solid state memory) that store processor readable code (e.g., software) for programming the one or more processors to perform the methods described herein. The host may also include additional system memory, one or more input/output interfaces and/or one or more input/output devices in communication with the one or more processors.

Other types of non-volatile memory in addition to NAND flash memory can also be used.

Semiconductor memory devices include volatile memory devices, such as dynamic random access memory (“DRAM”) or static random access memory (“SRAM”) devices, non-volatile memory devices, such as resistive random access memory (“ReRAM”), electrically erasable programmable read only memory (“EEPROM”), flash memory (which can also be considered a subset of EEPROM), ferroelectric random access memory (“FRAM”), and magnetoresistive random access memory (“MRAM”), and other semiconductor elements capable of storing information. Each type of memory device may have different configurations. For example, flash memory devices may be configured in a NAND or a NOR configuration.

The memory devices can be formed from passive and/or active elements, in any combinations. By way of non-limiting example, passive semiconductor memory elements include ReRAM device elements, which in some embodiments include a resistivity switching storage element, such as an anti-fuse or phase change material, and optionally a steering element, such as a diode or transistor. Further by way of non-limiting example, active semiconductor memory elements include EEPROM and flash memory device elements, which in some embodiments include elements containing a charge storage region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND string is an example of a set of series-connected transistors that comprise memory cells and SG transistors.

A NAND memory array may be configured so that the array is composed of multiple memory strings in which a string is composed of multiple memory elements sharing a single bit line and accessed as a group. Alternatively, memory elements may be configured so that each element is individually accessible, e.g., a NOR memory array. NAND and NOR memory configurations are examples, and memory elements may be otherwise configured. The semiconductor memory elements located within and/or over a substrate may be arranged in two or three dimensions, such as a two-dimensional memory structure or a three-dimensional memory structure.

In a two-dimensional memory structure, the semiconductor memory elements are arranged in a single plane or a single memory device level. Typically, in a two-dimensional memory structure, memory elements are arranged in a plane (e.g., in an x-y direction plane) which extends substantially parallel to a major surface of a substrate that supports the memory elements. The substrate may be a wafer over or in which the layer of the memory elements is formed or it may be a carrier substrate which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and word lines.

A three-dimensional memory array is arranged so that memory elements occupy multiple planes or multiple memory device levels, thereby forming a structure in three dimensions (i.e., in the x, y and z directions, where the z-direction is substantially perpendicular and the x-and y-directions are substantially parallel to the major surface of the substrate).

As a non-limiting example, a three-dimensional memory structure may be vertically arranged as a stack of multiple two-dimensional memory device levels. As another non-limiting example, a three-dimensional memory array may be arranged as multiple vertical columns (e.g., columns extending substantially perpendicular to the major surface of the substrate, i.e., in the y direction) with each column having multiple memory elements. The columns may be arranged in a two-dimensional configuration, e.g., in an x-y plane, resulting in a three-dimensional arrangement of memory elements with elements on multiple vertically stacked memory planes. Other configurations of memory elements in three dimensions can also constitute a three-dimensional memory array.

By way of non-limiting example, in a three-dimensional array of NAND strings, the memory elements may be coupled together to form a NAND string within a single horizontal (e.g., x-y) memory device level. Alternatively, the memory elements may be coupled together to form a vertical NAND string that traverses across multiple horizontal memory device levels. Other three-dimensional configurations can be envisioned wherein some NAND strings contain memory elements in a single memory level while other strings contain memory elements which span through multiple memory levels. Three-dimensional memory arrays may also be designed in a NOR configuration and in a ReRAM configuration.

Typically, in a monolithic three-dimensional memory array, one or more memory device levels are formed above a single substrate. Optionally, the monolithic three-dimensional memory array may also have one or more memory layers at least partially within the single substrate. As a non-limiting example, the substrate may include a semiconductor such as silicon. In a monolithic three-dimensional array, the layers constituting each memory device level of the array are typically formed on the layers of the underlying memory device levels of the array. However, layers of adjacent memory device levels of a monolithic three-dimensional memory array may be shared or have intervening layers between memory device levels.

Then again, two-dimensional arrays may be formed separately and then packaged together to form a non-monolithic memory device having multiple layers of memory. For example, non-monolithic stacked memories can be constructed by forming memory levels on separate substrates and then stacking the memory levels atop each other. The substrates may be thinned or removed from the memory device levels before stacking, but as the memory device levels are initially formed over separate substrates, the resulting memory arrays are not monolithic three-dimensional memory arrays. Further, multiple two-dimensional memory arrays or three-dimensional memory arrays (monolithic or non-monolithic) may be formed on separate chips and then packaged together to form a stacked-chip memory device.

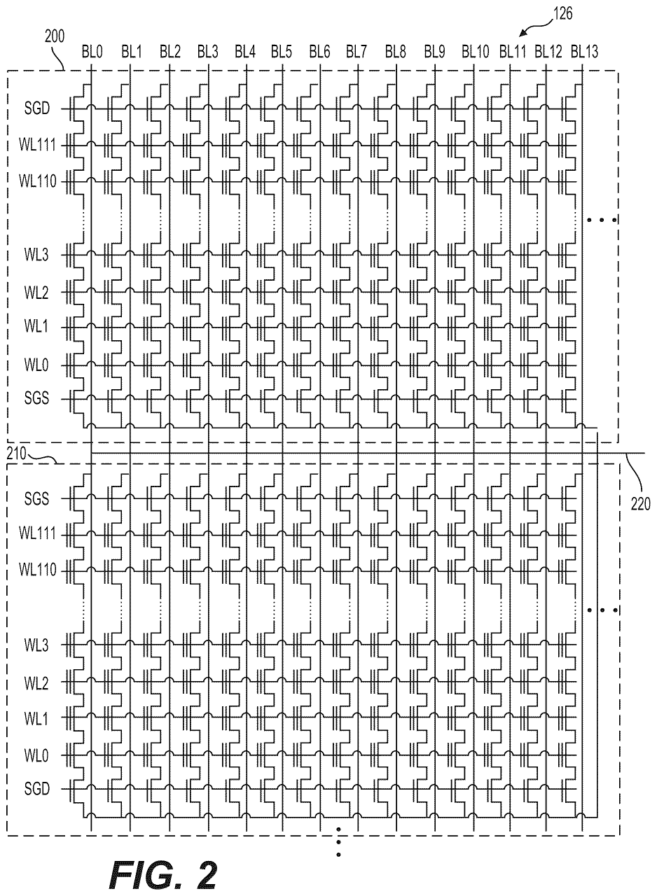

FIG. 2 illustrates memory blocks 200, 210 of memory cells in an example two-dimensional configuration of the memory array 126 of FIG. 1. The memory array 126 can include many such blocks 200, 210. Each example block 200, 210 includes a number of NAND strings and respective bit lines, e.g., BL0, BL1, . . . which are shared among the blocks. Each NAND string is connected at one end to a drain-side select gate (SGD), and the control gates of the drain-side select gates are connected via a common SGD line. The NAND strings are connected at their other end to a source-side select gate (SGS) which, in turn, is connected to a common source line 220. One hundred and twelve word lines, for example, WL0-WL111, extend between the SGSs and the SGDs. In some embodiments, the memory block may include more or fewer than one hundred and twelve word lines. For example, in some embodiments, a memory block includes one hundred and sixty-four word lines. In some cases, dummy word lines, which contain no user data, can also be used in the memory array adjacent to the select gate transistors or between certain data word lines. Such dummy word lines can shield the edge data word line from certain edge effects.

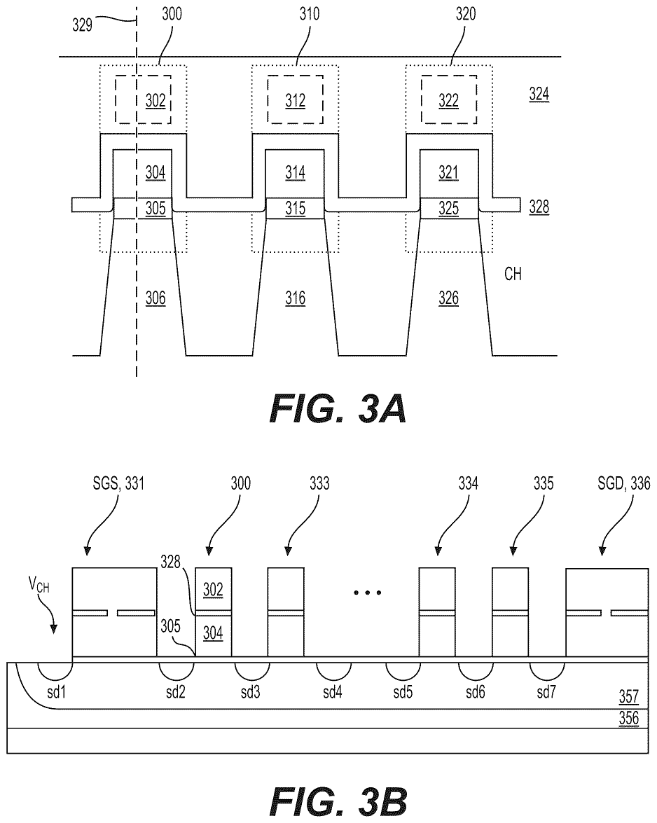

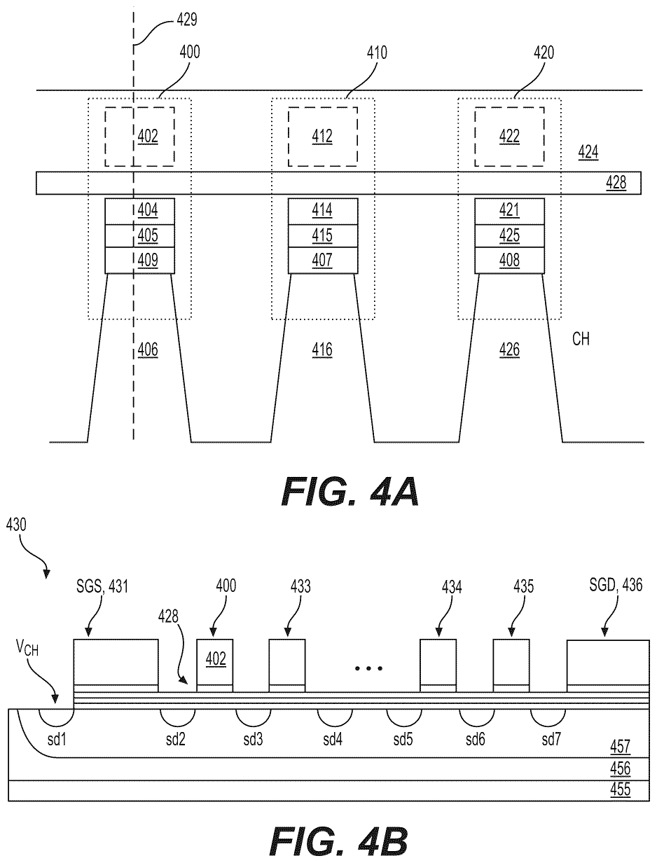

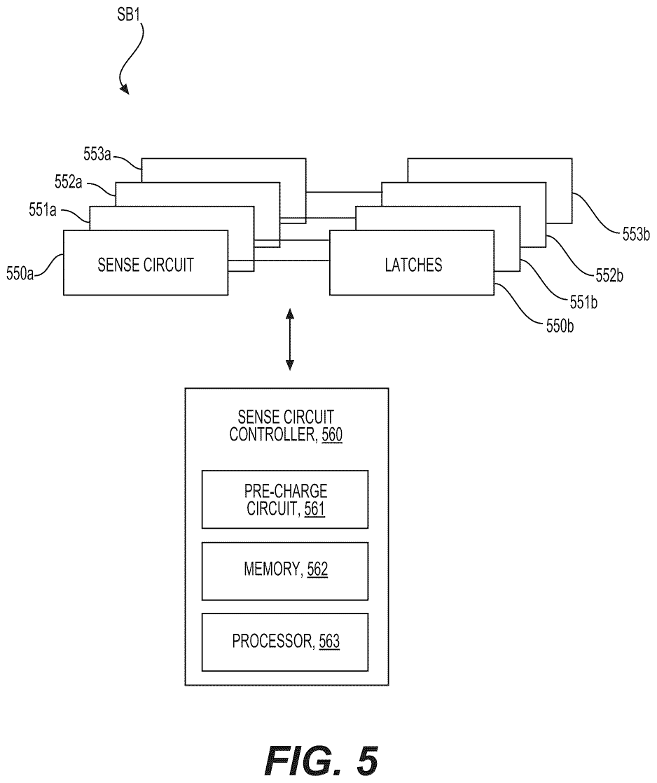

One type of non-volatile memory which may be provided in the memory array is a floating gate memory, such as of the type shown in FIGS. 3A and 3B. However, other types of non-volatile memory can also be used. As discussed in further detail below, in another example shown in FIGS. 4A and 4B, a charge-trapping memory cell uses a non-conductive dielectric material in place of a conductive floating gate to store charge in a non-volatile manner. A triple layer dielectric formed of silicon oxide, silicon nitride and silicon oxide (“ONO”) is sandwiched between a conductive control gate and a surface of a semi-conductive substrate above the memory cell channel. The cell is programmed by injecting electrons from the cell channel into the nitride, where they are trapped and stored in a limited region. This stored charge then changes the threshold voltage of a portion of the channel of the cell in a manner that is detectable. The cell is erased by injecting hot holes into the nitride. A similar cell can be provided in a split-gate configuration where a doped polysilicon gate extends over a portion of the memory cell channel to form a separate select transistor.

In another approach, NROM cells are used. Two bits, for example, are stored in each NROM cell, where an ONO dielectric layer extends across the channel between source and drain diffusions. The charge for one data bit is localized in the dielectric layer adjacent to the drain, and the charge for the other data bit localized in the dielectric layer adjacent to the source. Multi-state data storage is obtained by separately reading binary states of the spatially separated charge storage regions within the dielectric. Other types of non-volatile memory are also known.

FIG. 3A illustrates a cross-sectional view of example floating gate memory cells 300, 310, 320 in NAND strings. In this Figure, a bit line or NAND string direction goes into the page, and a word line direction goes from left to right. As an example, word line 324 extends across NAND strings which include respective channel regions 306, 316 and 326. The memory cell 300 includes a control gate 302, a floating gate 304, a tunnel oxide layer 305 and the channel region 306. The memory cell 310 includes a control gate 312, a floating gate 314, a tunnel oxide layer 315 and the channel region 316. The memory cell 320 includes a control gate 322, a floating gate 321, a tunnel oxide layer 325 and the channel region 326. Each memory cell 300, 310, 320 is in a different respective NAND string. An inter-poly dielectric (IPD) layer 328 is also illustrated. The control gates 302, 312, 322 are portions of the word line. A cross-sectional view along contact line connector 329 is provided in FIG. 3B.

The control gate 302, 312, 322 wraps around the floating gate 304, 314, 321, increasing the surface contact area between the control gate 302, 312, 322 and floating gate 304, 314, 321. This results in higher IPD capacitance, leading to a higher coupling ratio which makes programming and erase easier. However, as NAND memory devices are scaled down, the spacing between neighboring cells 300, 310, 320 becomes smaller so there is almost no space for the control gate 302, 312, 322 and the IPD layer 328 between two adjacent floating gates 302, 312, 322.

As an alternative, as shown in FIGS. 4A and 4B, the flat or planar memory cell 400, 410, 420 has been developed in which the control gate 402, 412, 422 is flat or planar; that is, it does not wrap around the floating gate and its only contact with the charge storage layer 428 is from above it. In this case, there is no advantage in having a tall floating gate. Instead, the floating gate is made much thinner. Further, the floating gate can be used to store charge, or a thin charge trap layer can be used to trap charge. This approach can avoid the issue of ballistic electron transport, where an electron can travel through the floating gate after tunneling through the tunnel oxide during programming.

FIG. 4A depicts a cross-sectional view of example charge-trapping memory cells 400, 410, 420 in NAND strings. The view is in a word line direction of memory cells 400, 410, 420 comprising a flat control gate and charge-trapping regions as a two-dimensional example of memory cells 400, 410, 420 in the memory cell array 126 of FIG. 1. Charge-trapping memory can be used in NOR and NAND flash memory device. This technology uses an insulator such as an SiN film to store electrons, in contrast to a floating-gate MOSFET technology which uses a conductor such as doped polycrystalline silicon to store electrons. As an example, a word line 424 extends across NAND strings which include respective channel regions 406, 416, 426. Portions of the word line provide control gates 402, 412, 422. Below the word line is an IPD layer 428, charge-trapping layers 404, 414, 421, polysilicon layers 405, 415, 425, and tunneling layers 409, 407, 408. Each charge-trapping layer 404, 414, 421 extends continuously in a respective NAND string. The flat configuration of the control gate can be made thinner than a floating gate. Additionally, the memory cells can be placed closer together.

FIG. 4B illustrates a cross-sectional view of the structure of FIG. 4A along contact line connector 429. The NAND string 430 includes an SGS transistor 431, example memory cells 400, 433, . . . 435, and an SGD transistor 436. Passageways in the IPD layer 428 in the SGS and SGD transistors 431, 436 allow the control gate layers 402 and floating gate layers to communicate. The control gate 402 and floating gate layers may be polysilicon and the tunnel oxide layer may be silicon oxide, for instance. The IPD layer 428 can be a stack of nitrides (N) and oxides (O) such as in a N—O—N—O—N configuration.

The NAND string may be formed on a substrate which comprises a p-type substrate region 455, an n-type well 456 and a p-type well 457. N-type source/drain diffusion regions sd1, sd2, sd3, sd4, sd5, sd6 and sd7 are formed in the p-type well. A channel voltage, Vch, may be applied directly to the channel region of the substrate.

FIG. 5 illustrates an example block diagram of the sense block SB1 of FIG. 1. In one approach, a sense block comprises multiple sense circuits. Each sense circuit is associated with data latches. For example, the example sense circuits 550a, 551a, 552a, and 553a are associated with the data latches 550b, 551b, 552b, and 553b, respectively. In one approach, different subsets of bit lines can be sensed using different respective sense blocks. This allows the processing load which is associated with the sense circuits to be divided up and handled by a respective processor in each sense block. For example, a sense circuit controller 560 in SB1 can communicate with the set of sense circuits and latches. The sense circuit controller 560 may include a pre-charge circuit 561 which provides a voltage to each sense circuit for setting a pre-charge voltage. In one possible approach, the voltage is provided to each sense circuit independently, e.g., via the data bus and a local bus. In another possible approach, a common voltage is provided to each sense circuit concurrently. The sense circuit controller 560 may also include a pre-charge circuit 561, a memory 562 and a processor 563. The memory 562 may store code which is executable by the processor to perform the functions described herein. These functions can include reading the latches 550b, 551b, 552b, 553b which are associated with the sense circuits 550a, 551a, 552a, 553a, setting bit values in the latches and providing voltages for setting pre-charge levels in sense nodes of the sense circuits 550a, 551a, 552a, 553a. Further example details of the sense circuit controller 560 and the sense circuits 550a, 551a, 552a, 553a are provided below.

In some embodiments, a memory cell may include a flag register that includes a set of latches storing flag bits. In some embodiments, a quantity of flag registers may correspond to a quantity of data states. In some embodiments, one or more flag registers may be used to control a type of verification technique used when verifying memory cells. In some embodiments, a flag bit's output may modify associated logic of the device, e.g., address decoding circuitry, such that a specified block of cells is selected. A bulk operation (e.g., an erase operation, etc.) may be carried out using the flags set in the flag register, or a combination of the flag register with the address register, as in implied addressing, or alternatively by straight addressing with the address register alone.

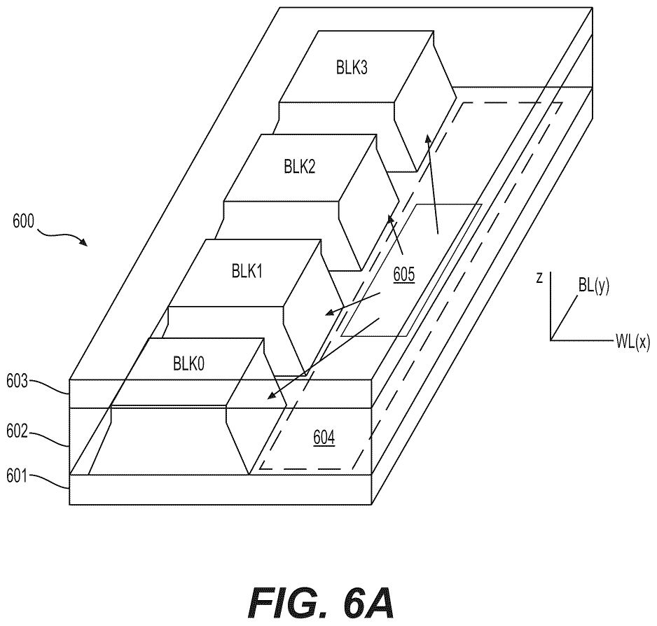

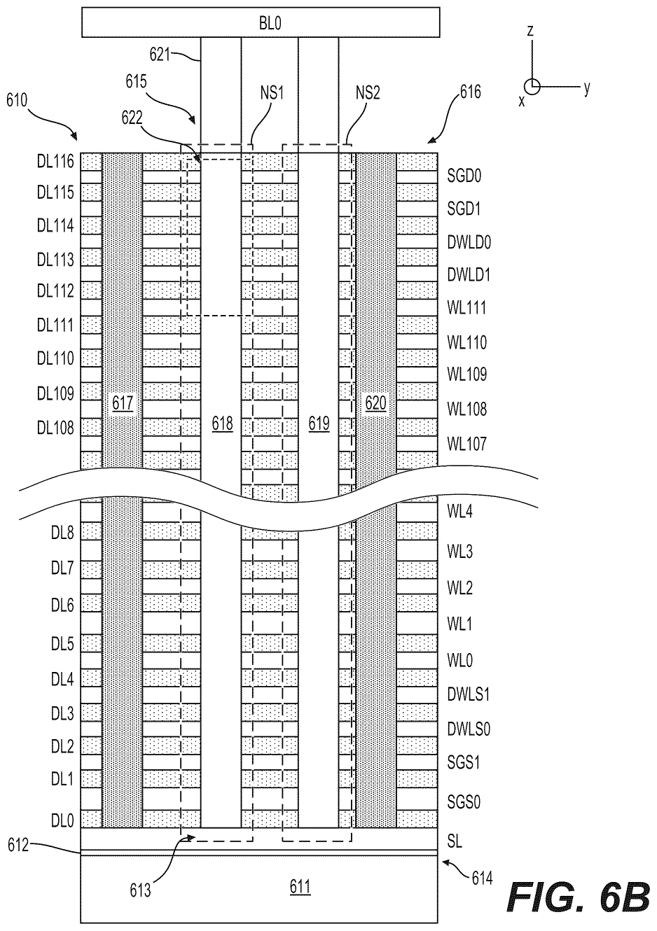

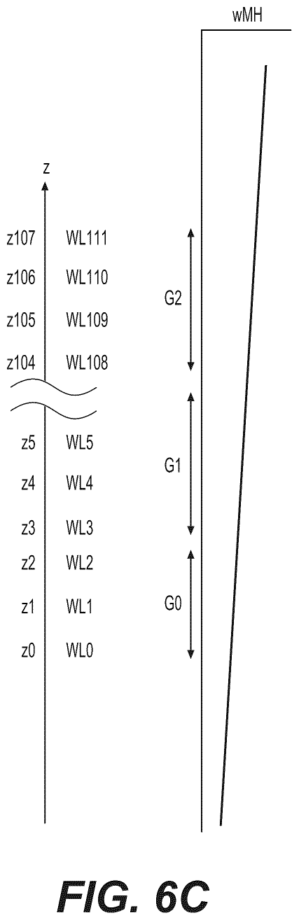

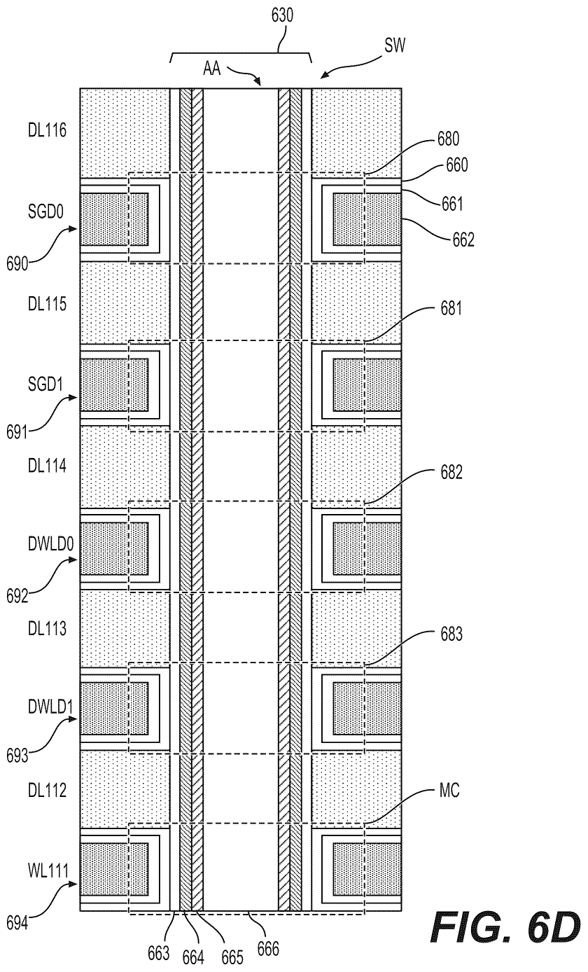

FIG. 6A is a perspective view of a set of blocks 600 in an example three-dimensional configuration of the memory array 126 of FIG. 1. On the substrate are example blocks BLK0, BLK1, BLK2, BLK3 of memory cells (storage elements) and a peripheral area 604 with circuitry for use by the blocks BLK0, BLK1, BLK2, BLK3. For example, the circuitry can include voltage drivers 605 which can be connected to control gate layers of the blocks BLK0, BLK1, BLK2, BLK3. In one approach, control gate layers at a common height in the blocks BLK0, BLK1, BLK2, BLK3 are commonly driven. The substrate 601 can also carry circuitry under the blocks BLK0, BLK1, BLK2, BLK3, along with one or more lower metal layers which are patterned in conductive paths to carry signals of the circuitry. The blocks BLK0, BLK1, BLK2, BLK3 are formed in an intermediate region 602 of the memory device. In an upper region 603 of the memory device, one or more upper metal layers are patterned in conductive paths to carry signals of the circuitry. Each block BLK0, BLK1, BLK2, BLK3 comprises a stacked area of memory cells, where alternating levels of the stack represent word lines. In one possible approach, each block BLK0, BLK1, BLK2, BLK3 has opposing tiered sides from which vertical contacts extend upward to an upper metal layer to form connections to conductive paths. While four blocks BLK0, BLK1, BLK2, BLK3 are illustrated as an example, two or more blocks can be used, extending in the x-and/or y-directions.

In one possible approach, the length of the plane, in the x-direction, represents a direction in which signal paths to word lines extend in the one or more upper metal layers (a word line or SGD line direction), and the width of the plane, in the y-direction, represents a direction in which signal paths to bit lines extend in the one or more upper metal layers (a bit line direction). The z-direction represents a height of the memory device.

FIG. 6B illustrates an example cross-sectional view of a portion of one of the blocks BLK0, BLK1, BLK2, BLK3 of FIG. 6A. The block comprises a stack 610 of alternating conductive and dielectric layers. In this example, the conductive layers comprise two SGD layers, two SGS layers and four dummy word line layers DWLD0, DWLD1, DWLS0 and DWLS1, in addition to data word line layers (word lines) WL0-WL111. The dielectric layers are labelled as DL0-DL116. Further, regions of the stack 610 which comprise NAND strings NS1 and NS2 are illustrated. Each NAND string encompasses a memory hole 618, 619 which is filled with materials which form memory cells adjacent to the word lines. A region 622 of the stack 610 is shown in greater detail in FIG. 6D and is discussed in further detail below. The dielectric layers can have variable thicknesses such that some of the conductive layers can be closer to or further from neighboring conductive layers. The thicknesses of the dielectric layers affect the “ON pitch,” which is a factor in memory density. Specifically, a smaller ON pitch allows for more memory cells in a given area but may compromise reliability.

The stack 610 includes a substrate 611, an insulating film 612 on the substrate 611, and a portion of a source line SL. NS1 has a source-end 613 at a bottom 614 of the stack and a drain-end 615 at a top 616 of the stack 610. Contact line connectors (e.g., slits, such as metal-filled slits) 617, 620 may be provided periodically across the stack 610 as interconnects which extend through the stack 610, such as to connect the source line to a particular contact line above the stack 610. The contact line connectors 617, 620 may be used during the formation of the word lines and subsequently filled with metal. A portion of a bit line BL0 is also illustrated. A conductive via 621 connects the drain-end 615 to BL0.

FIG. 6C illustrates a plot of memory hole diameter in the stack of FIG. 6B. The vertical axis is aligned with the stack of FIG. 6B and illustrates a width (wMH), e.g., diameter, of the memory holes 618 and 619. The word line layers WL0-WL111 of FIG. 6A are repeated as an example and are at respective heights z0-z111 in the stack. In such a memory device, the memory holes which are etched through the stack have a very high aspect ratio. For example, a depth-to-diameter ratio of about 25-30 is common. The memory holes may have a circular cross-section. Due to the etching process, the memory hole width can vary along the length of the hole. Typically, the diameter becomes progressively smaller from the top to the bottom of the memory hole. That is, the memory holes are tapered, narrowing at the bottom of the stack. In some cases, a slight narrowing occurs at the top of the hole near the select gate so that the diameter becomes slightly wider before becoming progressively smaller from the top to the bottom of the memory hole.

FIG. 6D illustrates a close-up view of the region 622 of the stack 610 of FIG. 6B. Memory cells are formed at the different levels of the stack at the intersection of a word line layer and a memory hole. In this example, SGD transistors 680, 681 are provided above dummy memory cells 682, 683 and a data memory cell MC. A number of layers can be deposited along the sidewall (SW) of the memory hole 630 and/or within each word line layer, e.g., using atomic layer deposition. For example, each column (e.g., the pillar which is formed by the materials within a memory hole 630) can include a charge-trapping layer or film 663 such as SiN or other nitride, a tunneling layer 664, a polysilicon body or channel 665, and a dielectric core 666. A word line layer can include a blocking oxide/block high-k material 660, a metal barrier 661, and a conductive metal such as Tungsten as a control gate. For example, control gates 690, 691, 692, 693, and 694 are provided. In this example, all of the layers except the metal are provided in the memory hole 630. In other approaches, some of the layers can be in the control gate layer. Additional pillars are similarly formed in the different memory holes. A pillar can form a columnar active area (AA) of a NAND string.

When a memory cell is programmed, electrons are stored in a portion of the charge-trapping layer which is associated with the memory cell. These electrons are drawn into the charge-trapping layer from the channel and through the tunneling layer. The threshold voltage Vt of a memory cell is increased in proportion to the amount of stored charge. During a sensing operation, the threshold voltage Vt is detected or measured. During an erase operation, the electrons return to the channel.

Each of the memory holes 630 can be filled with a plurality of annular layers comprising a blocking oxide layer, a charge trapping layer 663, a tunneling layer 664 and a channel layer. A core region of each of the memory holes 630 is filled with a body material, and the plurality of layers are between the core region and the word line layer in each of the memory holes 630. In some cases, the charge trapping layer 663 and the tunneling layer 664 are annular in shape. In other cases, as discussed in further detail below, these layers are semi-circular in shape.

The NAND string can be considered to have a floating body channel because the length of the channel is not formed on a substrate. Further, the NAND string is provided by a plurality of word line layers above one another in a stack and separated from one another by dielectric layers.

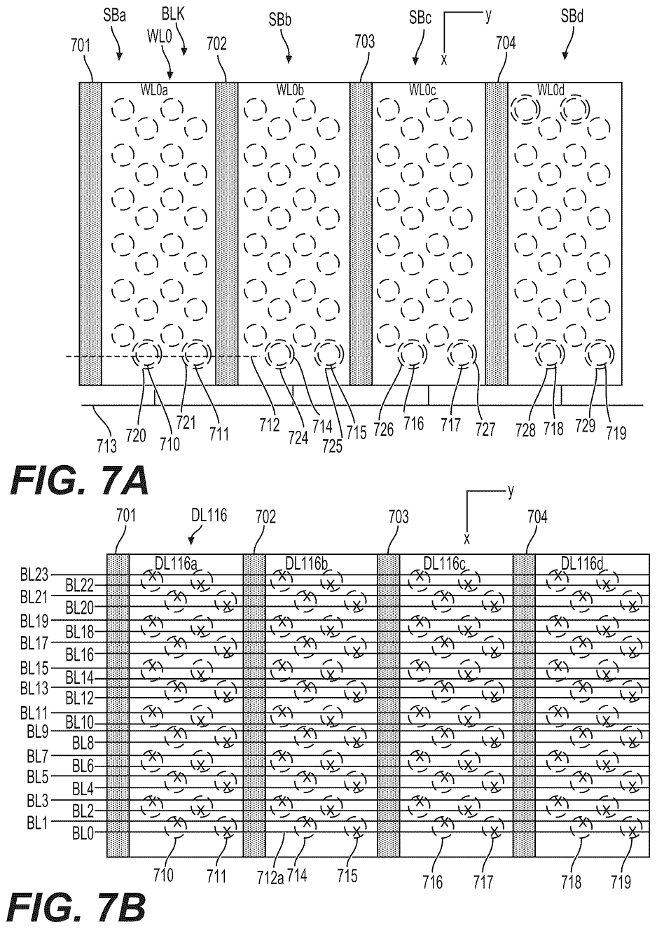

FIG. 7A illustrates a top view of an example word line layer WL0 of the stack 610 of FIG. 6B. As mentioned, a three-dimensional memory device can comprise a stack of alternating conductive and dielectric layers. The conductive layers provide the control gates of the SG transistors and memory cells. The layers used for the SG transistors are SG layers and the layers used for the memory cells are word line layers. Further, memory holes are formed in the stack and filled with a charge-trapping material and a channel material. As a result, a vertical NAND string is formed. Source lines are connected to the NAND strings below the stack and bit lines are connected to the NAND strings above the stack.

A block BLK in a three-dimensional memory device can be divided into sub-blocks, where each sub-block comprises a NAND string group which has a common SGD control line. Further, a word line layer in a block can be divided into regions. Each region is in a respective sub-block and can extend between contact line connectors (e.g., slits) which are formed periodically in the stack to process the word line layers during the fabrication process of the memory device. This processing can include replacing a sacrificial material of the word line layers with metal. Generally, the distance between contact line connectors should be relatively small to account for a limit in the distance that an etchant can travel laterally to remove the sacrificial material, and that the metal can travel to fill a void which is created by the removal of the sacrificial material. For example, the distance between contact line connectors may allow for a few rows of memory holes between adjacent contact line connectors. The layout of the memory holes and contact line connectors should also account for a limit in the number of bit lines which can extend across the region while each bit line is connected to a different memory cell. After processing the word line layers, the contact line connectors can optionally be filed with metal to provide an interconnect through the stack.

In this example, there are four rows of memory holes between adjacent contact line connectors. A row here is a group of memory holes which are aligned in the x-direction. Moreover, the rows of memory holes are in a staggered pattern to increase the density of the memory holes. The word line layer or word line is divided into regions WL0a, WL0b, WL0c and WL0d which are each connected by a contact line 713. The last region of a word line layer in a block can be connected to a first region of a word line layer in a next block, in one approach. The contact line 713, in turn, is connected to a voltage driver for the word line layer. The region WL0a has example memory holes 710, 711 along a contact line 712. The region WL0b has example memory holes 714, 715. The region WL0c has example memory holes 716, 717. The region WL0d has example memory holes 718, 719. The memory holes are also shown in FIG. 7B. Each memory hole can be part of a respective NAND string. For example, the memory holes 710, 714, 716 and 718 can be part of NAND strings NS0_SBa, NS1_SBb, NS2_SBc, NS3_SBd, and NS4_SBe, respectively.

Each circle represents the cross-section of a memory hole at a word line layer or SG layer. Example circles shown with dashed lines represent memory cells which are provided by the materials in the memory hole and by the adjacent word line layer. For example, memory cells 720, 721 are in WL0a, memory cells 724, 725 are in WL0b, memory cells 726, 727 are in WL0c, and memory cells 728, 729 are in WL0d. These memory cells are at a common height in the stack.

Contact line connectors (e.g., slits, such as metal-filled slits) 701, 702, 703, 704 may be located between and adjacent to the edges of the regions WL0a-WL0d. The contact line connectors 701, 702, 703, 704 provide a conductive path from the bottom of the stack to the top of the stack. For example, a source line at the bottom of the stack may be connected to a conductive line above the stack, where the conductive line is connected to a voltage driver in a peripheral region of the memory device.

FIG. 7B illustrates a top view of an example top dielectric layer DL116 of the stack of FIG. 6B. The dielectric layer is divided into regions DL116a, DL116b, DL116c and DL116d. Each region can be connected to a respective voltage driver. This allows a set of memory cells in one region of a word line layer being programmed concurrently, with each memory cell being in a respective NAND string which is connected to a respective bit line. A voltage can be set on each bit line during each programming, sensing, or erasing operation.

The region DL116a has the example memory holes 710, 711 along a contact line 712, which is coincident with a bit line BL0. A number of bit lines extend above the memory holes and are connected to the memory holes as indicated by the “X” symbols. BL0 is connected to a set of memory holes which includes the memory holes 711, 715, 717, 719. Another example bit line BL1 is connected to a set of memory holes which includes the memory holes 710, 714, 716, 718. The contact line connectors (e.g., slits, such as metal-filled slits) 701, 702, 703, 704 from FIG. 7A are also illustrated, as they extend vertically through the stack. The bit lines can be numbered in a sequence BL0-BL23 across the DL116 layer in the x-direction.

Different subsets of bit lines are connected to memory cells in different rows. For example, BL0, BL4, BL8, BL12, BL16, BL20 are connected to memory cells in a first row of cells at the right-hand edge of each region. BL2, BL6, BL10, BL14, BL18, BL22 are connected to memory cells in an adjacent row of cells, adjacent to the first row at the right-hand edge. BL3, BL7, BL11, BL15, BL19, BL23 are connected to memory cells in a first row of cells at the left-hand edge of each region. BL1, BL5, BL9, BL13, BL17, BL21 are connected to memory cells in an adjacent row of memory cells, adjacent to the first row at the left-hand edge.

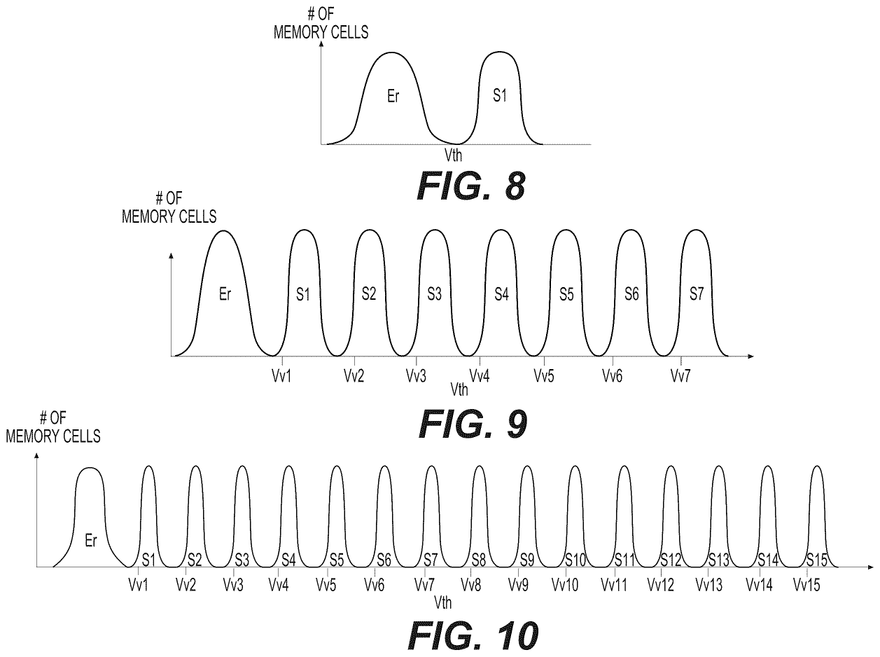

The memory cells of the memory blocks can be programmed to store one or more bits of data in multiple data states, each of which is associated with a respective threshold voltage Vt range. For example, FIG. 8 depicts a threshold voltage Vt distribution of a group of memory cells programmed according to a one bit per memory cell (SLC) storage scheme. In the SLC storage scheme, there are two total data states, including the erased state (Er) and a single programmed data state (S1). FIG. 9 illustrates the threshold voltage Vt distribution of a three bits per cell (TLC) storage scheme that includes eight total data states, namely the erased state (Er) and seven programmed data states (S1-S7). Each programmed data state (S1-S7) is associated with a respective verify voltage (Vv1-Vv7), which is employed during a verify portion of a programming operation as discussed in further detail below. FIG. 10 depicts a threshold voltage Vt distribution of a four bits per cell (QLC) storage scheme that includes sixteen total data states, namely the erased state (Er) and fifteen programmed data states (S1-S15). Other storage schemes are also available, such as two bits per cell (MLC) with eight data states or five bits per cell (PLC) with thirty-two data states.

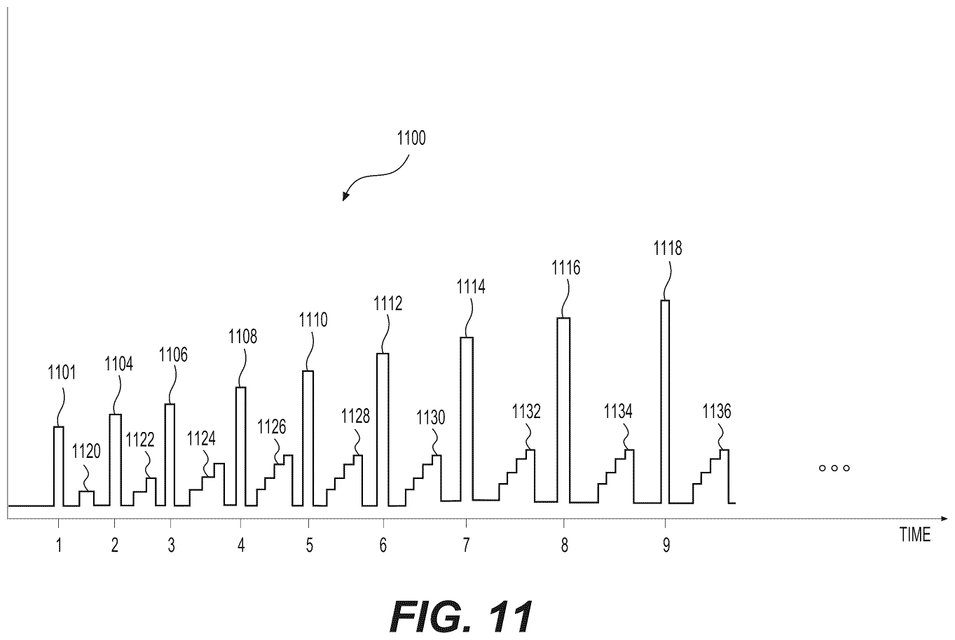

Programming to multiple bits per memory cell (for example, MLC, TLC, or QLC) typically includes a plurality of program loops. FIG. 11 depicts a waveform 1100 of the voltages applied to a selected word line during an example memory cell programming operation for programming the memory cells of the selected word line to a greater number of bits per memory cell (e.g., TLC or QLC). As depicted, each program loop includes a programming pulse VPGM and one or more verify pulses, depending on which data states are being programmed in a particular program loop. A square waveform is depicted for each pulse for simplicity; however, other shapes are possible, such as a multilevel shape or a ramped shape.

Incremental Step Pulse Programming (ISPP) is used in this example pulse train, which means that the VPGM pulse amplitude steps up, or increases, in each successive program loop. In other words, the pulse train includes VPGM pulses that increase stepwise in amplitude with each successive program loop by a fixed step size (dVPGM). A new pulse train starts with an initial VPGM pulse level VPGMU and ends at a final VPGM pulse level, which does not exceed a maximum allowed level. The example pulse train 1100 includes a series of VPGM pulses 1102-1118 that are applied to a selected word line that includes a set of non-volatile memory cells. One or more verify voltage pulses 1120-1136 are provided after each VPGM pulse as an example, based on the target data states which are being verified in the program loop. The verify voltages correspond with voltages Vv1-Vv7 shown in FIG. 9 or Vv1-Vv15 shown in FIG. 10. Concurrent with the application of the verify pulses, a sensing operation can determine whether a particular memory cell in the selected word line has a threshold voltage Vt above the verify voltage associated with its intended data state. If a selected memory cell is determined to have a threshold voltage Vt above the verify voltage of its intended data state, then that memory cell is said to have passed verify. When a memory cell passes verify, programming of that memory cell is completed and further programming of that memory cell is inhibited for all remaining program loops by applying an inhibit voltage to a bit line coupled with the memory cell concurrent with the VPGM pulse. Programming proceeds until all or a significant number of memory cells pass verify for their intended data states, in which case, programming passes, or until a predetermined maximum number of program loops is exceeded, in which case, programming fails. In some embodiments, the memory cells of a word line can be divided into a series of string groups, or simply strings, that can be programmed independently of one another, and programming can commence from one string to another across the word line before proceeding to the next word line in the memory block.

Programming of the memory cells of a selected word line can be conducted in either a full sequence programming operation or a multi-pass programming operation. In a full sequence programming operation, the memory cells are programmed directly to their intended data states in a single programming pass, e.g., the programming pass depicted in FIG. 11. In a multi-pass programming operation, the memory cells are programmed to their final programmed data states in two or more programming passes or stages, e.g., a first pass (hereinafter referred to as a “foggy pass”) and a second pass (hereinafter referred to as a “fine” pass). The pulse train of each of these programming passes may resemble the programming pass depicted in FIG. 11.

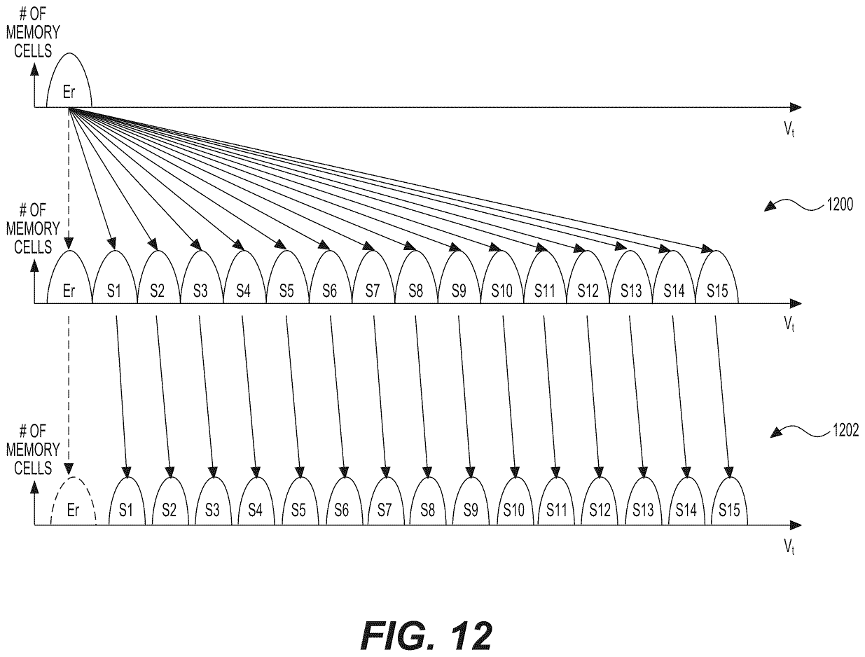

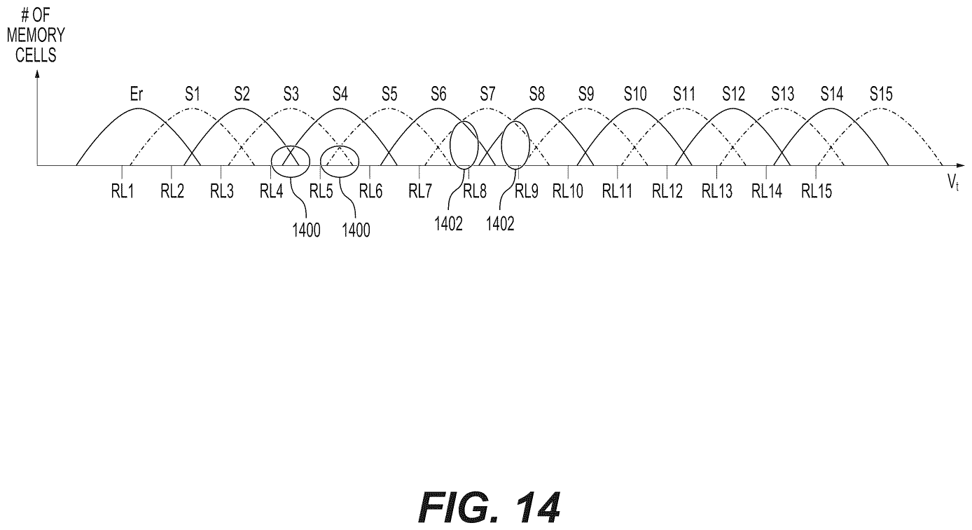

One example of a multi-pass programming operation to program the memory cells to the QLC storage scheme is schematically depicted in FIG. 12. In the foggy pass 1200, the memory cells are programmed quickly with a high step size dVPGM to approximately all of data states S1-S15, but each data state has a large or “fat” threshold voltage Vt distribution curve and the distribution curves overlap with one another (the overlapping curves is shown in FIG. 14 and discussed in further detail below). Because of the large threshold voltage Vt distributions, data is hereinafter referred to as foggy data 1200 and is not readable on its own. In the fine pass 1202, the memory cells are programmed more slowly (with a smaller step size dVPGM) and with higher accuracy to tighten and separate the threshold voltage Vt distribution curves such that the user data can be read without decoding.

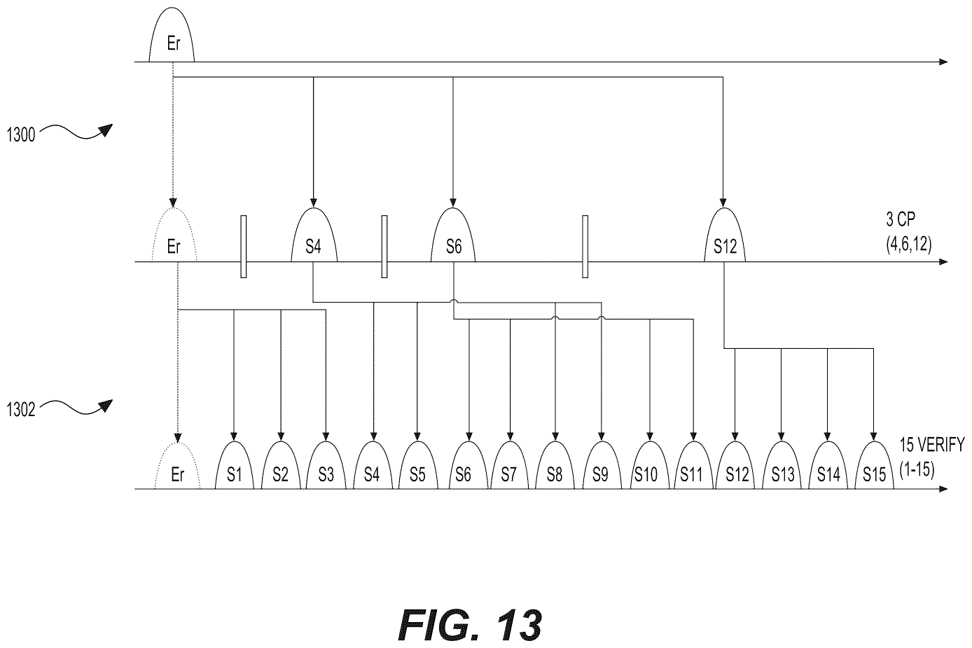

Another type of multi-pass programming operation, which is sometimes referred to as “MLC-Fine” is schematically depicted in FIG. 13. In a first pass 1300, rather than programming the memory cells to all of the programmed data states S1-S15 using low verify levels, the memory cells are programmed only to the S4, S6, and S12 data states. A relatively large voltage step size dVPGM may be used in the first pass. In a second pass 1302, the memory cells in the Er data state are either left in the erased state (Er) or are programmed to the S1, S2, or S3 data states; the memory cells in the S4 data state are either left in the S4 data state or programmed to the S5, S10, or S11 data states; the memory cells in the S6 data state are either left in the S6 data state or programmed to the S7, S10, or S11 data states; and the memory cells of the S12 data state are either left in the S12 data state or are programmed to the S13, S14, or S15 data states. In some embodiments, the first and second passes may take different forms. For example, the memory cells could be programmed to different or more data states in the first pass than the S4, S6, and S12 data states.

In some embodiments, in order to protect data from a problem sometimes referred to as neighboring word line interference (NWI), the fine pass is not performed immediately after the foggy pass is completed. Rather, the programming order includes performing the foggy pass on a specific word line WLn, followed by the foggy pass on a subsequent word line WLn+1, and then performing the fine pass on the specific word line WLn. For example, the programming order could be as follows: WLn (foggy pass), WLn+1 (foggy pass), WLn (fine pass), WLn+2 (fine pass), WLn+1 (fine pass), WLn+3 (foggy pass), WLn+2 (fine pass), WLn+4 (foggy pass), WLn+3 (fine pass) and so on. Both the foggy and fine passes may be performed on each word line one string group at a time.

Foggy-fine techniques generally offer better performance than MLC-fine techniques but present certain challenges. For instance, the foggy data (1200 in FIG. 12) written to a specific word line WLn is not readable after only the foggy pass because their threshold voltage Vt distribution curves overlap with one another. As such, according to some foggy-fine techniques, four pages of data for the word line WLn are stored in system cache (off-die) until the fine pass is completed. In an example, one known type of foggy-fine programming technique requires 1,792 kB of system cache. This approach also requires the transmission of four pages of data (16 data states) from the system/host to the die before each foggy pass and again before each fine pass. Consequently, for each word line being programmed, these four pages of data need to be transmitted from the system cache to the die twice, i.e., once before each of the two passes. In addition to requiring system resources, this frequent transmission of a significant amount of data from the system cache to the memory device also consumes a significant amount of power.

Although performance of MLC-fine programming is typically lower as compared to foggy-fine programming, MLC-fine programming offers a significant advantage in terms of system memory usage. This is due to the fact that the data (1300 in FIG. 13) programmed into the word line WLn during the MLC pass is readable. Consequently, at the onset of the fine pass for a word line WLn, two pages of data can be retrieved from the word line WLn in an internal data load (IDL) read operation, and only two pages of data have to be retrieved from the system cache. Thus, MLC-fine programming is more efficient than foggy-fine programming from a memory-efficiency standpoint but this efficiency comes at the cost of performance.

One aspect of the present disclosure is related to a multi-pass programming technique that offers improved performance (comparable to the foggy-fine techniques discussed above) at an improved memory-efficiency (comparable to or better than MLC-fine) and achieves these benefits by allowing the foggy data to be decoded so that the data being programmed to a word line does not have to remain stored in system cache between the foggy and fine passes, thereby reducing system resource usage. According to these techniques, following the foggy pass, two pages of parity data are also programmed into another memory block of the same memory die, namely, a parity block. Prior to the fine pass, the parity data is used to decode the foggy data to reconstruct the user data. Each data state is read and corrected in a descending order, i.e., S15 is read and decoded first; then S14 is read and decoded; then the S13 is read and decoded; then S12 is read and decoded; and so on. In an exemplary embodiment, the parity data is programmed into a parity memory block in the memory device.

FIG. 14 depicts a threshold voltage Vt distribution plot of a page of foggy data programmed according to an exemplary embodiment of the present disclosure. As illustrated, in some threshold voltage ranges 1400, the curves of three data states overlap with one another. On the other hand, in some other threshold voltage ranges 1402, the curves of only two data states overlap with one another. As discussed in further detail below, parity data is used to decode this foggy data so that the intended data states of memory cells in these regions with overlapping distribution curves can be deciphered prior to the fine pass.

As also illustrated in FIG. 14, each data state is associated with a read level voltage RLn that is below a lower tail of the distribution curve of the respective data state Sn. For example, read level voltage RL1 is below the lower tail of data state S1, read level voltage RL2 is below the lower tail of data state S2, read level voltage RL3 is below the lower tail of data state S3, and so on. The process of reading and decoding the foggy data involves performing a series of sensing operations using each of the read level voltages RL1-RL15 as reference voltages VCG in a descending order.

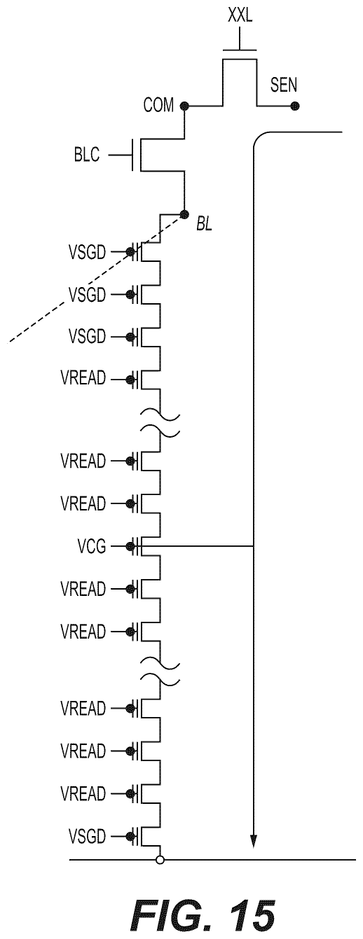

Turning now to FIG. 15, each sensing operation begins with a sense capacitor, which is electrically connected with a sense node SEN, being charged to a predetermined charged voltage. Simultaneously, all of the memory cells of a selected NAND string, with the exception of a selected memory cell of a selected word line, are turned on by a pass voltage VREAD. The reference voltage VCG (e.g., any of RL1-RL15) is applied to the selected word line. An XXL transistor is then turned on and the sensing capacitor is discharged through the NAND string. Since all of the memory cells of the NAND string are turned on by the pass voltage VREAD, the discharge current Icell is largely dictated by whether the reference voltage VCG did or did not turn on the selected memory cell, i.e., whether the threshold voltage Vt of the memory cell is above or below the reference voltage VCG. By repeating this process using the different read level voltages RL1-RL15 as the reference voltage VCG, the approximate threshold voltage Vt of each memory cell in the selected word line can be determined. More specifically, the foggy read operation determines the threshold voltage Vt range of each memory cell relative to the read levels, e.g., less than RL1; between RL1 and RL2; between RL2 and RL3; between RL3 and RL4; between RL4 and RL5; between RL5 and RL6; between RL6 and RL7; between RL7 and RL8; between RL8 and RL9; and so on.

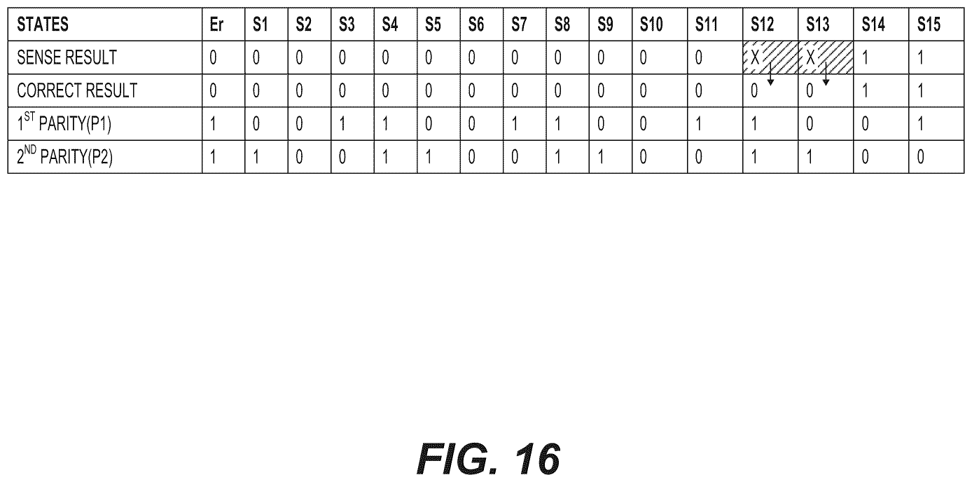

Due to the overlapping threshold voltage Vt distribution curves in the foggy data, it is not possible to read the data using the read level voltages RL1-RL15 alone. For example, if a memory cell is detected as having a threshold voltage Vt between RL14 and RL15, there are three different data states that this memory cell could be being programmed to, i.e., S12, S13, and S14. However, with reference to the table found in FIG. 16, using two parity bits to decode the foggy data, the intended data state for each memory cell can be determined. In this table, a “1” means that the threshold voltage Vt of the intended data state is greater than the read level, a “0” means it is less than the read level, and an “X” indicates a read error. The “correct result” row is what should be present for a memory cell being programmed to the S14 data state, i.e., 0s for data states Er-S13 and 1s for data states S14 and S15. The “sense result” row depicts what was sensed.

In this case, a memory cell is actually being programmed to the S14 data state. Thus, read errors (X's) are present in the “sense results” row for the S12 and S13 data states because those threshold voltage Vt distribution curves have upper tails that extend past the read level voltage RL14. In this example, if the first and second parity bits (p1, p2) are (1, 1) or (1, 0), then the read error is changed from X to 0, thereby producing the “correct result” and establishing that this particular memory cell is intended for the S14 data state.

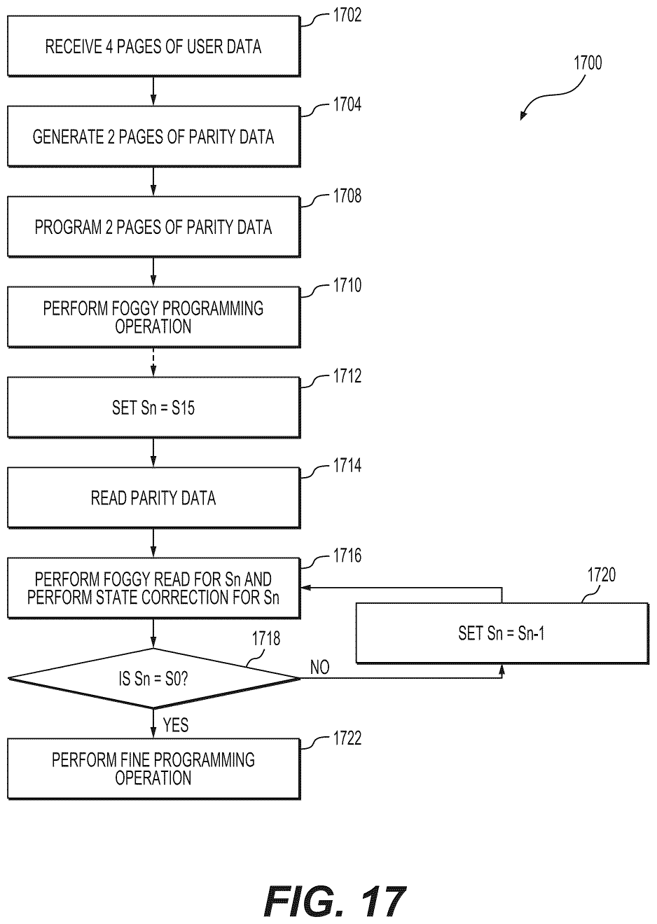

FIG. 17 is a flow chart 1700 depicting the steps of performing a foggy-fine programming operation according to an exemplary embodiment. These steps could be performed by the controller; a processor or processing device or any other circuitry, executing instructions stored in memory; and/or other circuitry described herein that is specifically configured/programmed to execute the following steps.

At step 1702, four pages of user data to be programmed into a selected word line WLn are received by the memory device. At step 1704, two pages of parity data (two bits of parity data per memory cell in the selected word line WLn) are generated to assist with decoding foggy data to reconstruct the four pages of user data at step 1714, as discussed in further detail below. At step 1708, the two pages of parity data are programmed to another location within the memory device, e.g., one or more dedicated parity memory blocks. In some embodiments, the two pages of parity data can be programmed into either one parity memory block in the MLC storage format or into two parity memory blocks in the SLC storage format.

At step 1710, a foggy programming operation is performed to program the user data into the word lines of the selected word line WLn. The foggy operation includes a plurality of program loops with VPGM pulses that increase in magnitude by a relatively large first step size dVPGM such that the foggy programming operation is completed relatively quickly. During the foggy operation, all fifteen (15) programmed data states are programmed into the memory cells of the selected word line WLn. In some embodiments, verify can be skipped for one or more of the data states and only performed on certain so-called “checkpoint” data states. Following the foggy operation, the threshold voltage Vt distribution of the foggy data will approximate the distribution illustrated in FIG. 14 such that the foggy data is unreadable without decoding. After step 1710, there is a gap in time while the memory device performs a programming operation on another word line, e.g., a fine pass on word line WLn−1.

When the other programming operation is completed, programming resumes in the selected word line WLn. At step 1712, a selected data state Sn is set to a last data state being programmed, e.g., S15 in the case of programming to the QLC storage format. At step 1714, the partity data is read and is loaded into data latches.

At step 1716, a foggy read operation is performed for data state Sn and at this same time, a state correction operation is performed for the data state Sn using the parity data to decode the foggy data. The foggy read operation determines the threshold voltage Vt range of each memory cell relative to the read levels, e.g., less than RL1; between RL1 and RL2; between RL2 and RL3; between RL3 and RL4; between RL4 and RL5; between RL5 and RL6; between RL6 and RL7; between RL7 and RL8; between RL8 and RL9; and so on. Using the determined threshold voltage Vt range and the parity data, during the state correction operation, the intended data state for each memory cell in the selected word line WLn is decoded. The data state correction operation then determines which of up to three possible data states in the respective voltage range is the intended data state.

At step 1718, it is determined if the selected data state Sn is the last data state S0 (or Er), i.e., the data state that is associated with the lowest threshold voltage Vt range. If the answer at decision step 1718 is “no,” then at step 1720, the selected data state Sn is incrementally reduced, e.g., Sn=Sn−1. The process then returns to step 1716.

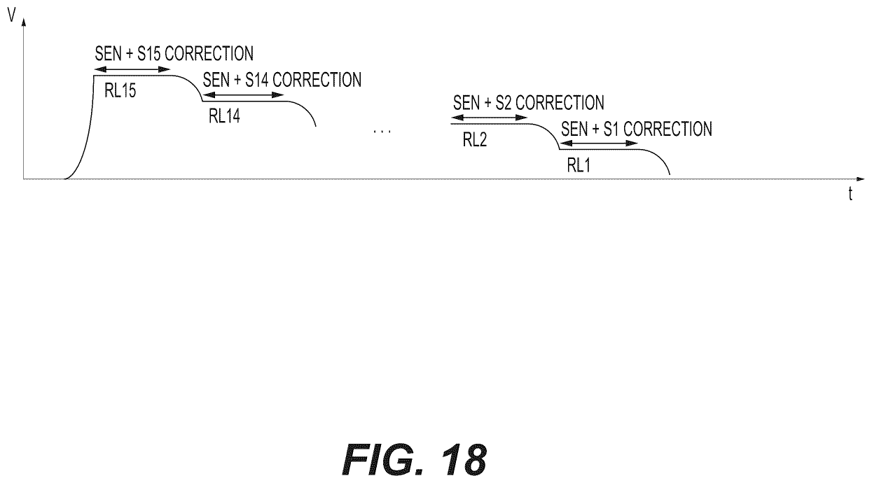

The process proceeds through steps 1716 through 1720 until the foggy read and data state correction operations have been performed, one data state at a time, on all of the programmed data states, i.e., S1-S15. FIG. 18 is a waveform plot of the voltage applied to a selected word line WLn during this process. As illustrated, the voltage steps down directly from RL15 to RL14 to RL13 to RL12 to RL11 and so on. In this plot, the differences between the read level voltages are exaggerated for illustrative effect, i.e., they are not drawn to scale. The process of discharging the voltage that is applied to the selected word line WLn from one read level to the next (for example, from RL15 to RL14 or from RL14 to RL13) is very quick as compared to ramping up from a lower read level to a higher read level.

Turning back to FIG. 17, if the answer at decision step 1718 is “yes,” then at step 1722, the method proceeds with the step of performing the fine pass to tighten up and separate all of the threshold voltage Vt distribution curves so that the user data can be read directly from the selected word line WLn without decoding. During the fine operation, the magnitude of the VPGM pulse increases by a second step size dVPGM that is less than the first step size. Following step 1722, the threshold voltage Vt distribution plot resembles FIG. 10.

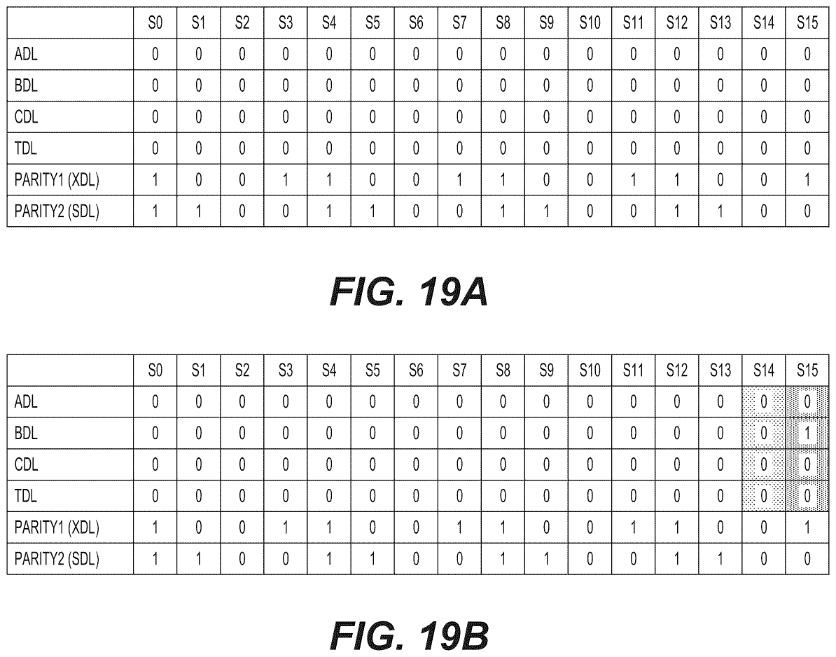

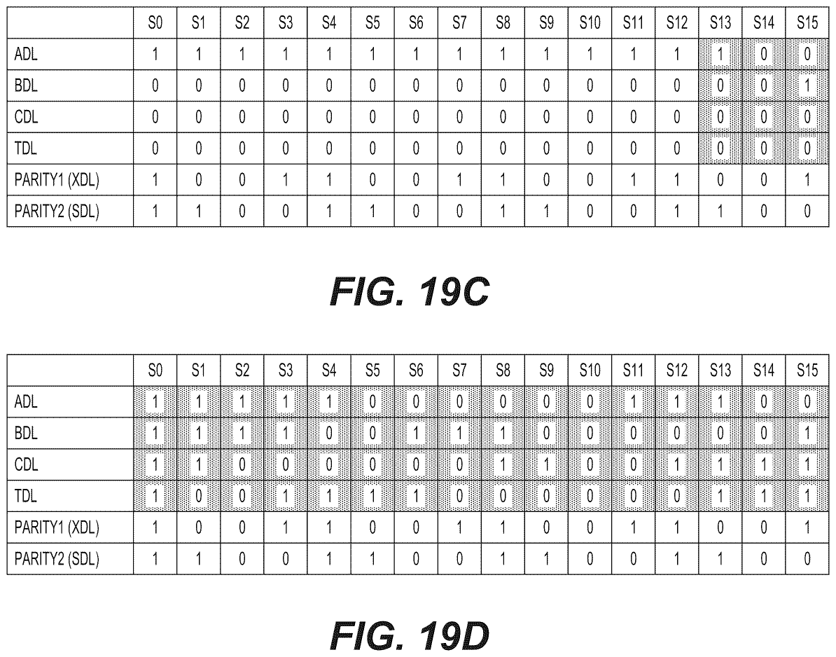

FIGS. 19A-19D illustrate the decoding process wherein correction is done for each state in descending order, i.e., starting with S15 and ending with S1. A total of six data latches (ADL, BDL, CDL, TDL, XDL, and SDL) are used to store the four pages of user data and the two pages of parity data until the fine pass. As illustrated in FIG. 19A, data latches ADL-TDL are all initially blank (all 0s). The table is filled in with each successive data correction operation. In this example, FIG. 19B illustrates the table after the S15 data state correction operation and FIG. 19C illustrates the table after the S14 data state correction operation. Finally, as illustrated in FIG. 19D, each data state is associated with its own respective series of bits, or code.

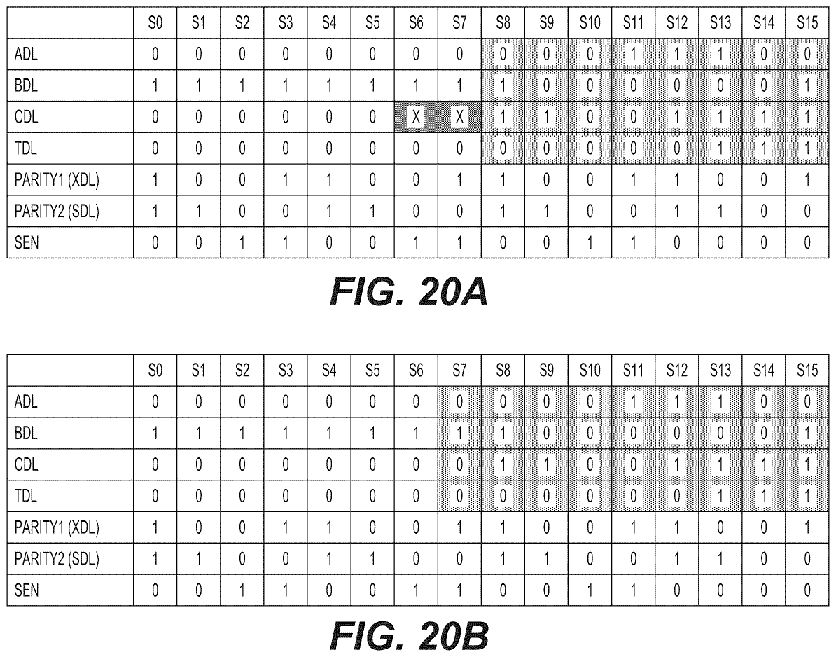

In some cases, when sensing, unknown bits will occur, and in an exemplary embodiment, the memory device is able to correct those errors by using the sensing capacitor SEN as a virtual data latch. For example, FIG. 20A depicts the data latch table following sensing using the RL8 reference voltage. As illustrated, there are X's in the data latch CDL for the S6 and S7 data states because the upper tails of these data states extend past the RL8 reference voltage (see FIG. 14). To correct these bits without the use of extra data latches, the exclusive AND logic operation is employed with data latches SDL and TDL as inputs, i.e., SEN=!SDL&!TDL. Next, the data latch CDL is set as a function of the logical operation NOT OR using the data latch CDL and the sense node SEN as inputs, i.e., !CDL=!CDL|SEN. Using these logical operations, in this example, the two X's (unknowns) for the S6 and S7 data states can be correctly changed to 0s. FIG. 20B illustrates the corrected table. This reduces the reliance on the data latch XDL, which may be slower than the other data latches, to correct failed bits.

Various terms are used herein to refer to particular system components. Different companies may refer to a same or similar component by different names and this description does not intend to distinguish between components that differ in name but not in function. To the extent that various functional units described in the following disclosure are referred to as “modules,” such a characterization is intended to not unduly restrict the range of potential implementation mechanisms. For example, a “module” could be implemented as a hardware circuit that includes customized very-large-scale integration (VLSI) circuits or gate arrays, or off-the-shelf semiconductors that include logic chips, transistors, or other discrete components. In a further example, a module may also be implemented in a programmable hardware device such as a field programmable gate array (FPGA), programmable array logic, a programmable logic device, or the like. Furthermore, a module may also, at least in part, be implemented by software executed by various types of processors. For example, a module may comprise a segment of executable code constituting one or more physical or logical blocks of computer instructions that translate into an object, process, or function. Also, it is not required that the executable portions of such a module be physically located together, but rather, may comprise disparate instructions that are stored in different locations and which, when executed together, comprise the identified module and achieve the stated purpose of that module. The executable code may comprise just a single instruction or a set of multiple instructions, as well as be distributed over different code segments, or among different programs, or across several memory devices, etc. In a software, or partial software, module implementation, the software portions may be stored on one or more computer-readable and/or executable storage media that include, but are not limited to, an electronic, magnetic, optical, electromagnetic, infrared, or semiconductor-based system, apparatus, or device, or any suitable combination thereof. In general, for purposes of the present disclosure, a computer-readable and/or executable storage medium may be comprised of any tangible and/or non-transitory medium that is capable of containing and/or storing a program for use by or in connection with an instruction execution system, apparatus, processor, or device.

Similarly, for the purposes of the present disclosure, the term “component” may be comprised of any tangible, physical, and non-transitory device. For example, a component may be in the form of a hardware logic circuit that is comprised of customized VLSI circuits, gate arrays, or other integrated circuits, or is comprised of off-the-shelf semiconductors that include logic chips, transistors, or other discrete components, or any other suitable mechanical and/or electronic devices. In addition, a component could also be implemented in programmable hardware devices such as field programmable gate arrays (FPGA), programmable array logic, programmable logic devices, etc. Furthermore, a component may be comprised of one or more silicon-based integrated circuit devices, such as chips, die, die planes, and packages, or other discrete electrical devices, in an electrical communication configuration with one or more other components via electrical conductors of, for example, a printed circuit board (PCB) or the like. Accordingly, a module, as defined above, may in certain embodiments, be embodied by or implemented as a component and, in some instances, the terms module and component may be used interchangeably.

Where the term “circuit” is used herein, it includes one or more electrical and/or electronic components that constitute one or more conductive pathways that allow for electrical current to flow. A circuit may be in the form of a closed-loop configuration or an open-loop configuration. In a closed-loop configuration, the circuit components may provide a return pathway for the electrical current. By contrast, in an open-looped configuration, the circuit components therein may still be regarded as forming a circuit despite not including a return pathway for the electrical current. For example, an integrated circuit is referred to as a circuit irrespective of whether the integrated circuit is coupled to ground (as a return pathway for the electrical current) or not. In certain exemplary embodiments, a circuit may comprise a set of integrated circuits, a sole integrated circuit, or a portion of an integrated circuit. For example, a circuit may include customized VLSI circuits, gate arrays, logic circuits, and/or other forms of integrated circuits, as well as may include off-the-shelf semiconductors such as logic chips, transistors, or other discrete devices. In a further example, a circuit may comprise one or more silicon-based integrated circuit devices, such as chips, die, die planes, and packages, or other discrete electrical devices, in an electrical communication configuration with one or more other components via electrical conductors of, for example, a printed circuit board (PCB). A circuit could also be implemented as a synthesized circuit with respect to a programmable hardware device such as a field programmable gate array (FPGA), programmable array logic, and/or programmable logic devices, etc. In other exemplary embodiments, a circuit may comprise a network of non-integrated electrical and/or electronic components (with or without integrated circuit devices). Accordingly, a module, as defined above, may in certain embodiments, be embodied by or implemented as a circuit.

It will be appreciated that example embodiments that are disclosed herein may be comprised of one or more microprocessors and particular stored computer program instructions that control the one or more microprocessors to implement, in conjunction with certain non-processor circuits and other elements, some, most, or all of the functions disclosed herein. Alternatively, some or all functions could be implemented by a state machine that has no stored program instructions, or in one or more application-specific integrated circuits (ASICs) or field-programmable gate arrays (FPGAs), in which each function or some combinations of certain of the functions are implemented as custom logic. A combination of these approaches may also be used. Further, references below to a “controller” shall be defined as comprising individual circuit components, an application-specific integrated circuit (ASIC), a microcontroller with controlling software, a digital signal processor (DSP), a field programmable gate array (FPGA), and/or a processor with controlling software, or combinations thereof.

Additionally, the terms “couple,” “coupled,” or “couples,” where may be used herein, are intended to mean either a direct or an indirect connection. Thus, if a first device couples, or is coupled to, a second device, that connection may be by way of a direct connection or through an indirect connection via other devices (or components) and connections.

Regarding, the use herein of terms such as “an embodiment,” “one embodiment,” an “exemplary embodiment,” a “particular embodiment,” or other similar terminology, these terms are intended to indicate that a specific feature, structure, function, operation, or characteristic described in connection with the embodiment is found in at least one embodiment of the present disclosure. Therefore, the appearances of phrases such as “in one embodiment,” “in an embodiment,” “in an exemplary embodiment,” etc., may, but do not necessarily, all refer to the same embodiment, but rather, mean “one or more but not all embodiments” unless expressly specified otherwise. Further, the terms “comprising,” “having,” “including,” and variations thereof, are used in an open-ended manner and, therefore, should be interpreted to mean “including, but not limited to . . . ” unless expressly specified otherwise. Also, an element that is preceded by “comprises . . . a” does not, without more constraints, preclude the existence of additional identical elements in the subject process, method, system, article, or apparatus that includes the element.

The terms “a,” “an,” and “the” also refer to “one or more” unless expressly specified otherwise. By way of example, “a processor” programmed to perform various functions refers to one processor programmed to perform each and every function or more than one processor collectively programmed to perform each of the various functions. In addition, the phrase “at least one of A and B” as may be used herein and/or in the following claims, whereby A and B are variables indicating a particular object or attribute, indicates a choice of A or B, or both A and B, similar to the phrase “and/or.” Where more than two variables are present in such a phrase, this phrase is hereby defined as including only one of the variables, any one of the variables, any combination (or sub-combination) of any of the variables, and all of the variables.

Further, where used herein, the term “about” or “approximately” applies to all numeric values, whether or not explicitly indicated. These terms generally refer to a range of numeric values that one of skill in the art would consider equivalent to the recited values (e.g., having the same function or result). In certain instances, these terms may include numeric values that are rounded to the nearest significant figure.

In addition, any enumerated listing of items that is set forth herein does not imply that any or all of the items listed are mutually exclusive and/or mutually inclusive of one another, unless expressly specified otherwise. Further, the term “set,” as used herein, shall be interpreted to mean “one or more,” and in the case of “sets,” shall be interpreted to mean multiples of (or a plurality of) “one or more,” “ones or more,” and/or “ones or mores” according to set theory, unless expressly specified otherwise.

The foregoing detailed description has been presented for purposes of illustration and description. It is not intended to be exhaustive or be limited to the precise form disclosed. Many modifications and variations are possible in light of the above description. The described embodiments were chosen to best explain the principles of the technology and its practical application to thereby enable others skilled in the art to best utilize the technology in various embodiments and with various modifications as are suited to the particular use contemplated. The scope of the technology is defined by the claims appended hereto.

What is claimed is:

1. A method of programming a memory device, comprising the steps of:
preparing a selected memory block, the selected memory block including an array of memory cells that are arranged in a plurality of word lines;
receiving instructions to program multiple pages of user data into a selected word line of the plurality of word lines;
in a first programming pass, programming the memory cells of the selected word line to a plurality of data states such that the selected word line contains foggy data;
programming parity data to a parity memory block;
reading the parity data;
reading the foggy data one data state at a time in a series of read operations and performing a decoding operation using the parity data during the reading of each data state prior to proceeding to read a next data state until all of the plurality of data states have been read and the user data has been decoded; and
further programming the memory cells in a second programming pass from the foggy data to the user data.

2. The method as set forth in claim 1, wherein the foggy data is read one data state at a time starting with a data state that is associated with a highest threshold voltage range and ending with a data state that is associated with a lowest threshold voltage range.

3. The method as set forth in claim 1, wherein the user data includes four pages of data.

4. The method as set forth in claim 3, wherein the parity data includes two pages of data.

5. The method as set forth in claim 1, wherein the plurality of data states includes at least fifteen programmed data states.

6. The method as set forth in claim 1, wherein the step of reading the parity data includes storing the parity data into data latches and wherein a sensing capacitor is used as a virtual data latch.

7. The method as set forth in claim 1, wherein the first programming pass includes a plurality of program loops with programming pulses and wherein a programming voltage increases by a first step size between program loops,
wherein the second programming pass includes a plurality of program loops with programming pulses and wherein the programming voltage increases by a second step size between program loops, and
wherein the second step size is less than the first step size.

8. A memory device, comprising:
a selected memory block including an array of memory cells that are arranged in a plurality of word lines;
circuitry for programming the memory cells of a selected word line of the plurality of word lines, the circuitry being configured to;
receive instructions to program multiple pages of user data into the selected word line,
in a first programming pass, program the memory cells of the selected word line to a plurality of data states such that the selected word line contains foggy data,
program parity data into a parity memory block,
read the parity data,
read the foggy data one data state at a time in a series of read operations and perform a decoding operation using the parity data during the reading of each data state prior to proceeding to read a next data state until all of the plurality of data states have been read and the user data has been decoded, and
further program the memory cells in a second programming pass from the foggy data to the user data.

9. The memory device as set forth in claim 8, wherein the circuitry is configured to read the foggy data one data state at a time starting with a data state that is associated with a highest threshold voltage range and ending with a data state that is associated with a lowest threshold voltage range.

10. The memory device as set forth in claim 8, wherein the user data includes four pages of data.

11. The memory device as set forth in claim 10, wherein the parity data includes two pages of data.

12. The memory device as set forth in claim 8, wherein the plurality of data states includes at least fifteen programmed data states.

13. The memory device as set forth in claim 8, wherein when reading the parity data, the circuitry is configured to store the parity data into data latches.

14. The memory device as set forth in claim 8, wherein the first programming pass includes a plurality of program loops with programming pulses and wherein a programming voltage increases by a first step size between program loops,
wherein the second programming pass includes a plurality of program loops with programming pulses and wherein the programming voltage increases by a second step size between program loops, and
wherein the second step size is less than the first step size.

15. An apparatus, comprising:
a selected memory block including an array of memory cells that are arranged in a plurality of word lines and including at least one parity memory block;
a programming means for programming the memory cells of a selected word line of the plurality of word lines, the programming means being configured to;
receive instructions to program multiple pages of user data into the selected word line,
in a first programming pass, program the memory cells of the selected word line to at least fifteen programmed data states such that the selected word line contains foggy data, the at least fifteen data states including a first data state that is associated with a first threshold voltage range and a last data state that is associated with a second threshold voltage range that is greater than the first threshold voltage range,
program at least two pages of parity data into the parity memory block,
read the parity data,
read the foggy data one data state at a time in a series of read operations starting with the last data state and ending at the first data state and perform a decoding operation using the parity data during the reading of each data state prior to proceeding to read a next data state until all of the at least fifteen data states have been read and the user data has been decoded, and
further program the memory cells in a second programming pass from the foggy data to the user data.

16. The apparatus as set forth in claim 15, wherein the foggy data includes threshold voltage distribution curves for each of the at least fifteen data states and wherein at least three threshold voltage distribution curves overlap for some threshold voltage ranges.

17. The apparatus as set forth in claim 15, wherein the user data includes four pages of data.

18. The apparatus as set forth in claim 17, wherein the parity data includes two pages of data.

19. The apparatus as set forth in claim 18, wherein the parity data is programmed in a single bit per memory cell storage format.

20. The apparatus as set forth in claim 15, wherein the first programming pass includes a plurality of program loops with programming pulses and wherein a programming voltage increases by a first step size between program loops,
wherein the second programming pass includes a plurality of program loops with programming pulses and wherein the programming voltage increases by a second step size between program loops, and
wherein the second step size is less than the first step size.
